(19) United States
(12) Patent Application Publication
(10) Pub. No.: US 2026/0293041 A1
(43) Pub. Date: Sep. 24, 2026

(54) TWO-POSITION COOLING SYSTEM FOR INTERCONNECT MODULE

(71) Applicant: Mellanox Technologies, Ltd., Yokneam (IL)

(72) Inventors: Ari Dantus, Maalot-tarshicha (IL); Eli Zatulovski, Nesher (IL); Yuval Blayer, Avtalyon (IL); Rom Becker, ramat Yishai (IL); Oren Weltsch, The Golan Heights (IL); Kfir Katz, Tivon (IL); Shalom Gurevich, Karmiel (IL); Jamal Mousa, Haifa (IL); Igal Gutman, HOD HASHARON (IL); Alex Garmash, Nesher (IL)

(21) Appl. No.: 19/085,446

(22) Filed: Mar. 20, 2025

(51) Int. Cl. H05K 7/20

(52) U.S. Cl. CPC H05K 7/20254; H05K 7/20772

(57) ABSTRACT

A system includes a sliding member configured to move a cold plate between a first configuration and a second configuration. In the first configuration the cold plate is positioned away from a surface of an interconnect module. In the second configuration the cold plate is positioned in thermal communication with the interconnect module.

### TECHNICAL FIELD

At least one embodiment pertains to cooling for one or more circuit components. For example, at least one embodiment pertains to a two-position cooling system for cooling an interconnect module.

### BACKGROUND

Circuit components such as CPUs, DPUs, and GPUs are often cooled by air cooling and/or by liquid cooling. Some interconnect components used to send and/or receive signals between computing circuits generate heat and are cooled using air cooling and/or liquid cooling. Providing adequate heat transfer from the interconnect device to a cooling device can be challenging.

### BRIEF DESCRIPTION OF DRAWINGS

Various embodiments in accordance with the present disclosure will be described with reference to the drawings, in which:

FIGS. 1A and 1B illustrate simplified side views of a two-position cooling system for an interconnect module, in accordance with at least some embodiments.

FIGS. 2A-E illustrate perspective views of components of a two-position cooling system for an interconnect module, in accordance with at least some embodiments.

FIGS. 3A-D are side schematic views illustrating forces in a two-position cooling system for an interconnect module, in accordance with at least some embodiments.

FIG. 3E is a simplified side view of a ramp feature used in a two-position cooling system for an interconnect module, in accordance with at least some embodiments.

FIG. 4A is a top-down view of a computing tray incorporating a two-position cooling system for an interconnect module, in accordance with at least some embodiments.

FIG. 4B is a top-down view of a cold plate for use in a two-position cooling system for an interconnect module, in accordance with at least some embodiments.

FIG. 5 is a flow diagram of an example method of using a two-position cooling system for an interconnect module, in accordance with at least some embodiments.

FIGS. 6A-6B illustrate a network architecture, in accordance with at least some embodiments.

FIG. 7 illustrates an example datacenter cooling system, according to at least some embodiments.

FIG. 8 illustrates a schematic diagram of a datacenter cooling system, according to at least some embodiments.

FIG. 9 illustrates a computer system, in accordance with at least some embodiments.

FIG. 10 is a block diagram that schematically illustrates a computing system, in accordance with at least some embodiments.

FIG. 11 illustrates an example computing environment, in accordance with at least one embodiment.

FIG. 12 illustrates an example network configuration of components that can be used to implement aspects of various embodiments.

FIG. 13 illustrates an example datacenter cooling system, according to at least some embodiments.

FIGS. 14A-B illustrate views of a transceiver module operatively coupled to a network adapter, in accordance with at least some embodiments.

FIG. 15 depicts exemplary scenarios for use of a transceiver, in accordance with at least some embodiments.

### DETAILED DESCRIPTION

High performance computing circuits often include powerful computing components such as processing devices (e.g., that may include graphical processing units (GPUs), central processing units (CPUs), data processing units (DPUs), memory, etc.). Such high-performance computing components are regularly implemented on a printed circuit board (PCB) having many other computing components and/or other circuit components. In at least one embodiment, an artificial intelligence (AI) data center infrastructure platform is provided. Examples of an AI data center infrastructure platform are Nvidia® DGX™ SuperPOD™ and DGX™ Foundry. In at least one embodiment, an AI data center infrastructure platform provides accelerated infrastructure and/or scalable performance tailored for AI such as machine learning (ML) and other high-performance computing (HPC) loads.

Data may be transmitted between computing devices (e.g., such as servers, switch units, switch trays, etc.) using transceiver modules. The interconnection between switches of different layers may be accomplished with optical links using active optical cables and optical transceivers implemented in a pluggable form factor (also referred to as “pluggables”). The optical interconnects may be configured to connect between chips or between different communication systems. For example, it might provide optical interconnecting for network interface controller (NIC) to switch, switch to switch, and/or chip to chip. Optical interconnects can be used in a variety of applications, such as switches, processing units (e.g., graphics processing units (GPUs), etc.). An optical interconnect can include an optical link (e.g., optical fiber) to transmit an optical signal. Optical interconnect bandwidth can be scaled by transmitting an optical signal including multiple wavelengths using the same optical link. In doing so, the transmitter is tuned to generate the optical signal including multiple carrier wavelengths. Moreover, each modulator of a modular array can be tuned to receive and modulate a respective carrier frequency. Ordering the multiple wavelengths can be important to ensure that the transmitter and receiver are properly communicating data contained within the optical signal.

In at least one example embodiment, the optical interconnect is part of a datacenter that corresponds to a collection of network devices, such as network switches (e.g., Ethernet switches, IP routers, multiservice platforms, various transmission network elements, legacy communication equipment, or in any other suitable communication system) connected with a collection of servers or compute nodes. A switch fabric serves to transfer the data between the switch ports. A switch fabric comprises one or more interconnect circuits, which may be arranged in various switch fabric architectures, e.g., m*m crossbar, Banyan, Benes, Omega, Clos, multi-plane, STS, TST, shared memory, buffered crossbar, any other suitable blocking or non-blocking architecture, or any applicable mixed architecture thereof. A switch fabric is realized in typical embodiments by hardware, which may comprise Field-Programmable Gate Arrays (FPGAs) and/or Application-Specific Integrated Circuits (ASICs), and in some implementations also bus interconnects. The datacenter may adhere to a networking topology (e.g., a hierarchal networking topology), such as a fat tree topology, a Slim Fly topology, a Dragonfly topology, and/or the like. The datacenter routes traffic amongst the network switches and servers therein, and at least one layer of the topology in the datacenter is coupled to the communication network to allow networking traffic to flow between the datacenter and the network device(s).

The optical interconnect may include a substrate and an electro-optical component (VCSEL, photodiode, etc.) supported by the substrate and configured to convert between electrical and optical signals. The optical interconnect may further include a transmission block defining a receiving surface configured to receive an optical fiber, and a waveguide configured to transmit optical signals between the electro-optical component and the receiving surface such that in an operational configuration in which the receiving surface receives an optical fiber, the electro-optical component and the optical fiber are in optical communication.

While the present disclosure illustrates and describes the optical interconnect without a housing or other protective casing, as would be understood by one of ordinary skill in the art in light of the present disclosure, some or all of the optical interconnect may be supported or enclosed by any housing used in communications systems to protect the components supported therein (e.g., as part of Quad Small Form-factor Pluggable (QSFP) connectors, Small Form Pluggable (SFP) connectors, or the like). Furthermore, the substrate hosting the electro-optical component may be substantially rectangular shape and/or may be dimensioned (e.g., sized and shaped) for use in any communication system regardless of geometric constraints (e.g., L-shaped, squared-shaped, etc.).

In various embodiments, an optical interconnect for receiving an optical fiber may be implemented in a flip-chip configuration. In certain embodiments, the optical interconnect is configured as a flip-chip component such that a longitudinal axis of the first adiabatic transition profile of the optical interconnect and a longitudinal axis of the second adiabatic transition profile of the optical interconnect may be collinear. Said differently, the orientation of the optical interconnect in such an embodiment does not require a mirror or other reflective surface to redirect optical signals between the electro-optical component and the receiving surface. As would be evident to one of ordinary skill in the art in light of the present disclosure, however, the optical interconnect in a flip-chip configuration may also include one or more mirrors (e.g., reflective surfaces) to accommodate optical fibers received at varying angles. In some optical interconnect embodiments, only mirrors may be operationally configured to redirect light given that at some bending radii, light may remain confined to the waveguide. Accordingly, embodiments of a field replaceable modular optical interconnect unit are described that are configured to be received by a main switch system box. The field replaceable modular optical interconnect unit comprises a housing comprising at least a front panel, a rear panel, and side panels extending between the front and rear panels, a printed circuit board assembly supported within the housing, an optical module supported on the printed circuit board assembly and configured to convert between optical signals and corresponding electrical signals for respectively transmitting or receiving optical signals through a fiber optic cable, a board-to-board connector disposed on the rear panel of the housing and configured to enable electrical signals to be transmitted between the printed circuit board assembly and a main switch system box, and an external connector disposed on the front panel of the housing and configured to engage an external optical fiber for transmitting optical signals between the optical module and an external component. The field replaceable modular optical interconnect unit may be configured to be electrically connected to the main switch system box via engagement of the board-to-board connector with a corresponding connector of the main switch system box when the housing is received by the main switch system box.

In some embodiments, the optical module may be a mid-board optical module (MBOM), and/or the field replaceable modular optical interconnect unit may comprise a plurality of external connectors. For example, the external connector may be a first external connector, and the field replaceable modular optical interconnect unit may further comprise a second external connector disposed on the front panel of the housing and configured to enable transmission of electrical signals between the printed circuit board assembly and an external component connected thereto.

An optical interconnect typically comprises a driver circuit which drives an electro-optical element such as a light emitter (typically with a binary signal), a waveguide (typically an optical fiber), and a receiver. In such a setup the light emitter typically consumes a significant part of the power requirement of the optical interconnect. An optical interconnect is typically composed by a transceiver module in each end adapted to transmit optical information along one or two optical fibers. The transmitter of each transceiver typically comprises a driver circuit coupled to a light source and a receiver circuit coupled to a photo detector. Typically optical fibers are used as transmission medium in which case the light source and photo detector will be coupled to fibers. A driver circuit (often located on a driver chip) is a circuit tailored to generate a waveform appropriate to drive a light emitting device in response to an input signal which is typically a binary data stream. The combination of a driver circuit and a light source is referred to as a transmitter. A receiver circuit (often located on a receiver chip) is a circuit tailored to receive the output from the light detector and generate a corresponding binary data stream. The combination of a receiver circuit and a photodetector is referred to as a receiver. Often the receivers and transmitters provide multiple channels, i.e. the ability to transmit or receive via multiple light sources or photodetectors. Sometimes driver and receiver circuits are combined on the same chip which is then referred to as a transceiver chip. Besides driver, receiver and/or transceiver chips, optical modules may comprise further chips and electronics such as e.g. a microcontroller. Typically, the binary signal used in such optical links is an amplitude modulated NRZ signal but other signal types are in principle possible.

In a typical optical interconnect Vertical Cavity Surface Emitting Laser (VCSEL) diodes are utilized as light emitters to transmit binary data over optical fibers. However, the light source may in principle be any suitable light source and the transmitted waveform may be any suitable waveform for transmitting information. Most light emitters have a threshold current above which they substantially begin to emit light. Increasing the current driven through the emitter from zero to above said threshold may be time consuming, and therefore a bias current is typically driven through the light source. Often the bias current is set just below, at the threshold or above the threshold, but it may also be set to be well above threshold. This bias current is often programmable so as the same circuit design may be utilized to drive different light emitters and/or be used for different applications. Additional time varying current which modulates the emission from the light emitter is referred to as the modulation current.

In some embodiments, the disclosed technique provides an EO interconnect assembly comprising a pair of pluggable EO transceivers connected at respective ends of an optical fiber. The EO transceivers are typically used to connect network-connected devices (e.g., remote client switches, network adapters such as Network Interface controllers (NICs) and Host Channel Adapters (HCAs), Smart-NICs (NICs having embedded CPUs), network-enabled Graphics Processing Units (GPUs), and the like). The terms “network-connected device” and “network device” are used interchangeably herein. In certain embodiments, an optical interconnect includes a substrate, one or more optical waveguides, one or more first micro-lenses, one or more second micro-lenses, and first and second mechanical fixtures. Moreover, when designing an optical interconnect module, it is highly desirable to place the EO component driving circuitry in close proximity to the EO transducers, in order to maintain high signal integrity. As a result, however, heat generated in the driving circuitry may increase the junction temperatures of the transducers and thus degrade their performance. In order to resolve the above-described heat removal issues, the disclosed optical interconnect modules comprise cooling elements that are highly-integrated with the other elements of the optical interconnect module. In particular, the optical interconnect module typically comprises a light coupling module for coupling the optical signals between the optical fibers and the optoelectronic transducers. The light coupling module comprises light coupling elements such as micro-lenses or prisms. In the disclosed embodiments, this light coupling module additionally serves as a baseplate for the cooling elements. The resulting mechanical design is extremely compact and yet efficient in removing heat. The light coupling module is also referred to herein as an integrated optical cooling core.

Transceiver modules plug into receptacles of a computing device chassis to connect to the computing components and/or switches in the chassis. Transceiver modules often generate high amounts of heat and may be cooled using liquid cooling via cold plates. To improve the rate of heat transfer, a thermal interface pad may be included between a transceiver module and a cold plate. Spring pressure may push the cold plate against the surface of the transceiver module, effectively sandwiching the thermal interface pad between the cold plate and the transceiver module. The thermal interface pad may be made of a fragile thermal interface material (TIM) such as graphene. In conventional arrangements, during insertion of the transceiver module into the receptacle, the top surface of the transceiver module may push against the thermal interface pad on the bottom surface of the cold plate. Shear and friction forces may be generated in the thermal interface pad (when the transceiver module is being plugged into or removed from the receptacle) and the pad may become damaged. To avoid damage to the thermal interface pad, a protective layer can be included on the pad. However, the protective layer decreases the thermal transfer capability of the thermal interface pad, reduce the thermal performance because the protective layer added thermal resistance, which compromised the overall cooling efficiency. Moreover, this protective layer deteriorates after repeated module insertions, compromising the cooling system's effectiveness.

Aspects of the present disclosure address the deficiencies described above and other challenges by providing a system for coupling and de-coupling the transceiver module in a receptacle (e.g., of a switch and/or server chassis) without damaging the thermal interface pad and without inclusion of a protective layer appropriately managing thermal resistance and mechanical reliability over multiple insertions, during module insertion in high-performance systems.

In some embodiments, the cold plate is supported by and/or attached to a sliding member. The sliding member can be in one of two positions in some embodiments. For example, the sliding member may be in a first position when a transceiver module is not coupled within the receptacle and in a second position when the transceiver module is coupled within the receptacle. When the transceiver module is inserted into the receptacle, the transceiver module pushes the sliding member, causing the sliding member to move from the first position to the second position. When in the first position, the sliding member supports the cold plate above and away from the transceiver module (e.g., by exerting a force on the cold plate using one or more springs). When in the second position, the sliding member lowers the cold plate to the transceiver module so the top surface of the transceiver module contacts the thermal interface pad on the bottom of the cold plate enabling an efficient thermal contact and improving heat dissipation. Heat can then be transferred from the transceiver module to the cold plate via the thermal interface pad. The sliding member moves to the second position (and lowers the cold plate) when the transceiver module is fully inserted into the receptacle. For example, insertion of the transceiver module into the receptacle may include pushing the transceiver module against the spring, which may cause the sliding member to transition from the first position to the second position. By supporting the cold plate away from the surface of the transceiver module during insertion of the transceiver module into the receptacle (and only allowing cold plate to lower onto the transceiver module once the module is fully inserted), contact between the surface of the transceiver module and the thermal interface pad during the insertion process can be minimized and/or avoided, eliminating or reducing shear forces on the thermal interface pad regardless of vertical pressure. Consequently, damage to the thermal interface pad can also be minimized and/or avoided without inclusion of a protective layer. Thus, heat can be efficiently transferred from the transceiver module to the cold plate via the thermal interface pad.

Advantages of the present disclosure include, but are not limited to, for example, improved cooling for a transceiver module. Because no protective layer on the TIM pad is needed, heat can more efficiently flow from the transceiver module to the cold plate via the TIM pad. Moreover, damage to the TIM pad may be reduced by supporting the cold plate away from the transceiver module when the transceiver module is being inserted or removed from the receptacle. Because damage to the TIM pad may be reduced, cost savings may be realized because of the decreased frequency at which TIM pads are repaired and/or replaced. Additionally, embodiments of the present disclosure provide a system that can be repeatedly assembled/disassembled without damage (e.g., to the TIM pad) unlike prior solutions.

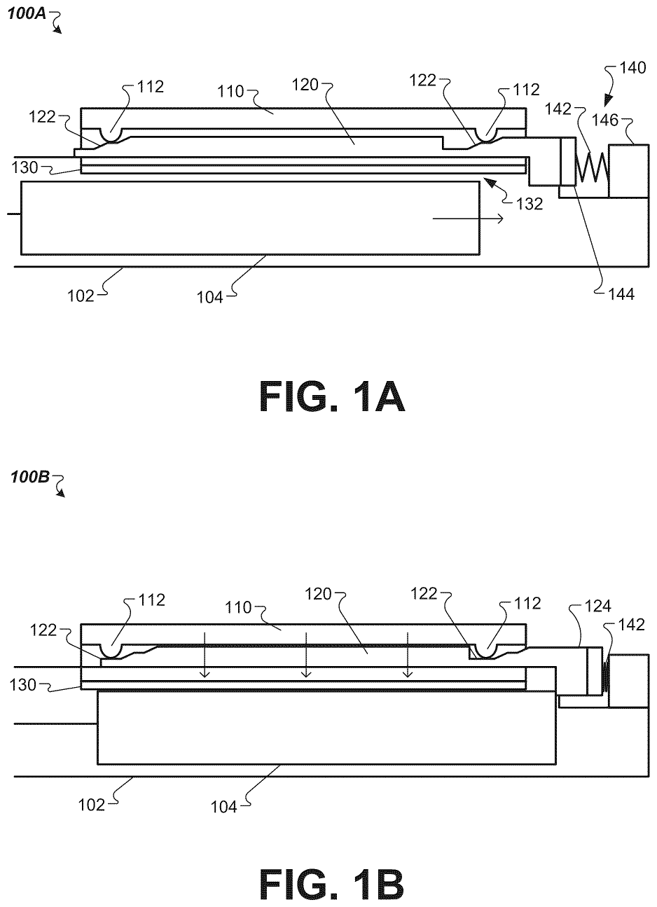

FIGS. 1A and 1B illustrate simplified cross sectional side views of a two-position cooling system for an interconnect module, in accordance with at least some embodiments. FIG. 1A shows a first configuration 100A of the system. FIG. 1B shows a second configuration 100B of the system.

Referring to FIG. 1A, an interconnect module 104 is partially inserted into a receptacle 102. The receptacle 102 may form a cage into which the interconnect module 104 can be inserted. The receptacle 102 may include features that interact with corresponding features on the interconnect module 104 to guide the interconnect module 104 as the interconnect module 104 is inserted into the receptacle 102. In some embodiments, the interconnect module 104 is an optical transceiver. The interconnect module 104 may send and/or receive electrical signals and/or optical signals to and/or from another remote computing unit, such as a server or switch tray. In some embodiments, a sliding member 120 associated with the receptacle 102 is configured to translationally slide between a first translational position and a second translational position. The sliding member 120 is shown in the first translational position in FIG. 1A. The insertion of the interconnect module 104 into the receptacle 102 may cause the sliding member 120 to slide from the first translational position to the second translational position. More details are discussed below at least with respect to FIG. 1B. While the interconnect module 104 is inserted into the receptacle 102 and before the interconnection module 104 engages with a contact region 124 of the sliding member 120, the sliding member 120 supports a cold plate 110 at a first vertical position (as shown in FIG. 1A). Additionally, removal of the interconnection module 104 from the receptacle 102 causes the sliding member 120 to lift the cold plate 110 to the first vertical position. The cold plate 110 may be configured to cool the interconnect module 104 when the interconnect module 104 is fully inserted into the receptacle 102 (as shown in FIG. 1B) and the cold plate 110 is in a second vertical position in which it contacts the interconnect module 104. In an alternative arrangement, such as where the receptacle 102 is oriented vertically or where the cold plate 110 is disposed beside the interconnect module 104 rather than above, the first vertical position (of the cold plate 110) may correspond to a first horizontal position and the second vertical position may correspond to a second horizontal position. In some embodiments, the cold plate 110 moves along an axis that is orthogonal to the movement of the interconnect module 104 and/or to the movement of the sliding member 120.

Sliding of the sliding member 120 may adjust the height of cold plate 110. In some embodiments, the sliding member 120 adjusts the distance from the cold plate 110 to the interconnect module 104. In the first vertical position (e.g., the first height, first distance from the interconnect module, etc.), the cold plate 110 is supported away from the top surface of the interconnect module 104. In some embodiments, a gap 132 exists between the top surface of the interconnect module 104 and the bottom surface of a TIM pad 130 attached on the bottom surface of the cold plate 110 while the sliding member 120 is in the first translational position. The bottom surface of the cold plate 110 may be a cooling surface of the cold plate. In some embodiments, the gap 132 is between approximately 0.2 mm wide and approximately 0.7 mm wide. In some embodiments, the gap 132 is approximately 0.6 mm wide. The gap 132 may allow the interconnect module 104 to be at least partially inserted (e.g., mostly inserted) into the receptacle 102 without the top surface of the interconnect module 104 contacting the TIM pad 130. In some embodiments, the TIM pad 130 is made of a heat-conducting material such as graphene. The TIM pad 130 may be fragile. If the interconnect module 104 were to contact the TIM pad 130 during insertion (into the receptacle 102), the interconnect module 104 may damage the TIM pad 130. By supporting the cold plate 110 at the first vertical position (e.g., at the first height, at the first distance, etc.), the TIM pad does not contact the interconnect module and therefore damage to the TIP pad 130 can be avoided (e.g., because of the gap 132).

The cold plate 110 may be supported by skids (e.g. wheels) 112 that interact with ramps 122 formed in the sliding member 120, in some embodiments. In some embodiments, the skids 112 move along the ramps 122 (e.g., up and down the ramps 122) during insertion and removal of the interconnect module 104 from the receptacle 102. The skids 112 may be at least partially rounded protrusions extending from the body of the cold plate 110. The skids 112 may be a metal or a plastic. In some embodiments, the skids 112 are constructed of the same material as the body of the cold plate 110. The skids 112 may be formed on both side of the cold plate 110. In some embodiments, the cold plate 110 includes four skids 112 (e.g., two skids 112 on each side of the cold plate). In some embodiments, the sliding member 120 includes four ramps 122 corresponding to the four skids 112.

In some embodiments, the cold plate 110 may be locked translationally so that the cold plate 110 may only move up and down with respect to the receptacle 102, without lateral motion. The sliding member 120 may be substantially restricted to side to side motion (as illustrated), which may correspond to the directions in which the interconnect module 104 is inserted and removed from receptacle 102. The side-to-side translational movement of the sliding member 120 along a first axis while the cold plate 110 remains stationary along that first axis (e.g., a side-to-side axis, as illustrated). In some embodiments, the side-to-side translational movement of the sliding member 120 along the first axis while the cold plate 110 remains stationary along the first axis may cause the skids 112 to move up and down the ramps 122, optionally along a second axis that may be orthogonal to the first axis. Movement of the skids 112 up and down the ramps 122 may cause the cold plate 110 to move up and down with respect to the sliding member 120. In some embodiments, the cold plate 110 moves along the second axis that is orthogonal to the first axis along which the sliding member 120 may move. As shown in FIG. 1A, the skids 112 are disposed at an upper portion of the ramps 122, causing the cold plate 110 to be supported (e.g., by the sliding member 120) at the first vertical position.

As described herein, the first and second vertical positions refer to the frame of reference as shown in the figures. However, other orientations are possible. For example, the first and second vertical positions of the cold plate 110 may instead by first and second horizontal positions in some embodiments (e.g., horizontal with respect to the sliding member 120). In some embodiments, the sliding member 120 may move along a first axis and the cold plate 110 may move along a second axis orthogonal to the first axis. In some embodiments, the second axis is arranged vertically. In some embodiments, the second axis is arranged horizontally. Regardless of the orientation of the second axis (e.g., whether vertical or horizontal), in some embodiments, the second axis is orthogonal to the first axis.

In some embodiments, a push-back assembly 140 pushes on the sliding member 120 to cause the default position of the sliding member 120 to be the first translational position. Therefore, the default position of the cold plate 110 may be the first vertical position. The push-back assembly 140 includes a spring 142 that pushes against a pushing member 144 and a spring mount 146. The spring mount 146 may be rigidly coupled with the receptacle 102. In some embodiments, a spring (not illustrated) pushes against the cold plate 110 in a direction toward the interconnect module 104. The spring 142 may impart a spring force on the sliding member 120 to overcome the spring force imparted on the cold plate 110.

Referring to FIG. 1B, as the interconnect module 104 reaches a threshold position in the receptacle 102 (e.g., while the interconnect module 104 is inserted into the receptacle 102), the interconnect module 104 may push against a contact region 124 of the sliding member 120. In some embodiments, the threshold position corresponds to the final approximately 2-3 mm of travel before the interconnect module 104 is fully inserted into the receptacle. In some embodiments, the threshold position is a distance from full insertion (of the interconnect module) corresponding to the difference between the first translational position of the sliding member 120 and the second translational position of the sliding member 120. As the interconnect module 104 is fully inserted into the receptacle 102 (e.g., past the threshold position), the sliding member 120 may move to the second translational position (shown in FIG. 1B). In some embodiments, the interconnect module 104 is to push the sliding member 120 from the first translational position to the second translational position. The spring 142 may be compressed. The spring 142 may exert a spring force on the sliding member 120 in a direction corresponding to movement of the sliding member 120 from the second translational position (shown in FIG. 1B) to the first translational position (shown in FIG. 1A) (e.g., opposite the movement of the sliding member 120 from the first translational position to the second translational position). If the interconnect module 104 were removed from the receptacle 102, the spring 142 may push the sliding member back to the first translational position shown in FIG. 1A.

The sliding member 120 may be pushed by insertion of the interconnect module 104 into the receptacle 102. In some embodiments, as the sliding member translationally slides from the first translational position to the second translational position, the skids 112 may move (e.g., slide) down the ramps 122. A spring (e.g., one or more springs, not illustrated) may push the cold plate 110 in a direction toward the interconnect module 104 (e.g., down) and into thermal contact with the interconnect module 104. As shown in FIG. 1B, the skids 112 are disposed at a lower portion of the ramps 122, allowing the spring force to push the cold plate 110 downwards to the second vertical position (e.g., the second height). In some embodiments, the spring force pushes the cold plate 110 along an axis perpendicular to the movement of the sliding member 120. In the second vertical position, the TIM pad 130 contacts the top surface of the interconnect module 104 so that heat can be transferred from the interconnect module 104 to the cold plate (e.g., via the TIM pad 130). Shear forces in the TIM pad 130 caused by movement of the interconnect module 104 relative to the TIM pad 130 may be distributed over substantially the entire surface of the TIM pad 130. In some embodiments, the thermal interface between the interconnect module 104 and the cold plate 110 has a thermal resistance less than approximately 0.5 Kelvin per Watt (K/W). In some embodiments, the thermal interface between the interconnect module 104 and the cold plate 110 has a thermal resistance less than approximately 0.2 K/W. In some embodiments, the TIM pad 130 has a thermal conductivity between approximately 15 Watts per meter Kelvin and approximately 45 Watts per meter Kelvin. In some embodiments, the TIM pad 130 has a thermal conductivity of about 30 Watts per meter Kevlin. Heat may be transferred from the interconnect module 104 to the cold plate 110 (e.g., via the TIM pad 130) when the cold plate 110 is in the second vertical position shown in FIG. 1B.

When the interconnect module 104 is removed from the receptacle 102, the TIM pad 130 may initially be in contact with the top surface of the interconnect module 104. As the interconnect module 104 is removed from the receptacle 102, the spring 142 may push the sliding member 120 from the second translational position towards the first translational position. As the spring 142 pushes the sliding member, the skids 112 may move (e.g., slide) up along the ramps 122, causing the cold plate 110 to move upwards from the second vertical position towards the first vertical position, establishing a gap between the top surface of the interconnect module 104 and the TIM pad 130. In some embodiments, the cold plate 110 moves away from the interconnect module 104 along an axis perpendicular to the movement of the sliding member 120. The interconnect module 104 can then be fully removed from the receptacle without contacting the TIM pad 130. Adjustment of the height of the cold plate 110 (e.g., between the first height and/or second height, between the first distance and/or the second distance from the interconnect module 104, etc.) may minimize the shear force on the TIM pad 130 during insertion and/or removal of the interconnect module. For example, when the sliding member 120 is in the first translational position, the cold plate 110 may be adjusted to the first height (e.g., first vertical position, first distance from the interconnect module 104, etc.) with a gap between the TIM pad 130 and the interconnect module 104. The interconnect module 104 can be moved (e.g., inserted or removed) without contacting the TIM pad 130. When the sliding member 120 is in the second translational position, the cold plate 110 may be adjusted to the second height (e.g., second vertical position, second distance from the interconnect module 104, etc.) with the TIM pad 130 contacting the interconnect module 104. The TIM pad 130 may contact the interconnect module 104 when the interconnect module 104 is fully inserted into the receptacle 102, thus minimizing the shear forces imparted by insertion of the interconnect module 104 on the TIM pad 130.

In some embodiments, the system illustrated in FIGS. 1A and 1B is configured to receive a plurality of insertions and removals of the interconnect module 104 (e.g., into the receptacle 102) without damage to the TIM pad 130 and/or without mechanical failure of the sliding member 120. For example, the interconnect module 104 can be inserted into and/or removed from the receptacle 102 at least one hundred times without substantially damaging the TIM pad 130.

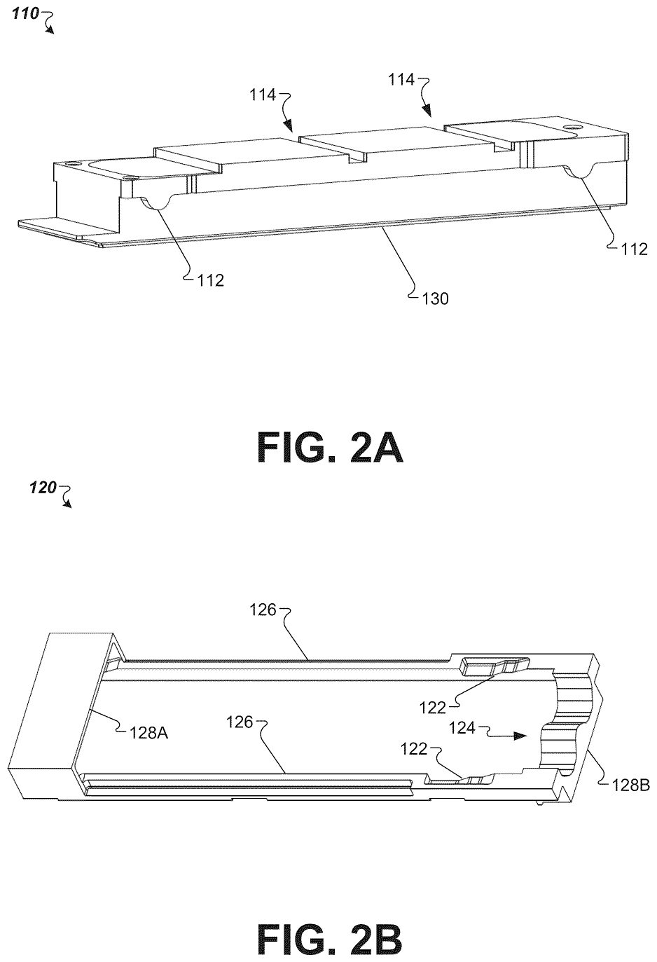

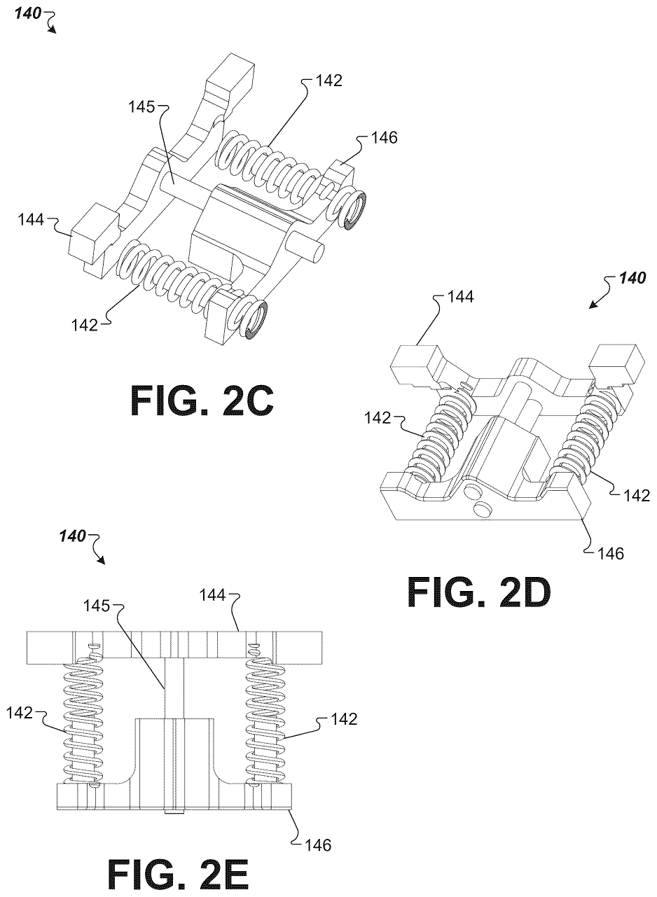

FIG. 2A illustrates a perspective view of a cold plate 110. In some embodiments, cold plate 110 is to cool interconnect module 104. The TIM pad 130 may be attached on the bottom surface of the cold plate 110. As discussed herein above, the TIM pad 130 may be made of a thermal interface material such as graphene. As discussed herein above, in the final 2-3 mm of insertion, the module pushes the mechanism, and the cold plate 110 moves down to touch the interconnect module 104. This minimizes shear movement, allowing the use of soft, high-conductivity TIMs like graphene-based TIMs, which may significantly reduce thermal resistance by 60-70%. The bottom surface of the cold plate 110 may be a cooling surface. In some embodiments, the cold plate 110 receives a flow of coolant (e.g., via a coolant inlet). Heat received at the cooling surface may be transferred to the coolant. The heated coolant may be expelled from the cold plate 110 (e.g., via a coolant outlet). The expelled coolant may be cooled, such as by a datacenter cooling system.

The cold plate 110 may form multiple members to support the cold plate. In some embodiments, skids 112 protrude on the sides of the cold plate 110. The skids may be at least partially rounded to easily slide along the surfaces of ramps 122. In some embodiments, the cold plate 110 can move vertically between a first vertical position and a second vertical position. The second vertical position may be lower than the first vertical position. In some embodiments, one or more springs (not illustrated) exerts a downward spring force on the cold plate 110. In some embodiments, the spring force on the cold plate is in a direction orthogonal to the movement of the sliding member 120. The cold plate 110 may form grooves 114 to interface with the springs. For example, the springs may sit at least partially within the grooves 114 and may push against the top surface of the cold plate 110. The springs may exert a spring force on the cold plate 110 in a direction toward the interconnect module.

In at least one embodiment, a cold plate is a metal plate that can be thermally coupled with an electronic device (e.g., a computing component) such as a CPU or a GPU, or an interconnect module, etc. In at least one embodiment, a cold plate can implement localized cooling of powered electronics by transferring heat from an electronic device to a liquid coolant that flows to a remote heat exchanger. In at least one embodiment, a cold plate includes a thick metal plate having one or more internal passages (e.g. finger shaped) through which liquid coolant can flow to dissipate heat from the modules. The liquid flows through the internal passages in a loop (e.g. interconnected fingers), cooling multiple internal passages in series. In at least one embodiment, a cold plate can be made of a material such as aluminum, steel, stainless steel, or copper. In at least one embodiment, an electronic device (such as an interconnect module) in contact with a cold plate is cooled by conduction. Heat from an electronic device may conduct from a device to an attached cold plate. Heat may be carried away by liquid coolant flowing through a cold plate.

FIG. 2B illustrates a perspective view of a sliding member 120. In some embodiments, sliding member 120 can translationally slide between a first translational position and a second translational position. When the interconnect module 104 is inserted into the receptacle 102, the interconnect module 104 may push against the contact region 124 to move the sliding member 120 from the first translational position to the second translational position. In some embodiments, the contact region 124 is formed on a surface of a bridge member 128B. The sliding member 120 includes bridge member 128A and 128B to couple parallel members 126. The bridge members may provide structural rigidity to the sliding member 120. The parallel members 126 may be substantially parallel to one another. The bridge members 128A,B may be substantially orthogonal to the parallel members 126. In some embodiments, the bridge member 128B forms cutouts to provide clearance to coolant lines coupled with the coolant inlet and outlet ports of the cold plate 110. In some embodiments, the parallel members 126 each form ramps 122. The skids 112 of the cold plate 110 may move along the surfaces of the ramps 122 to move the cold plate 110 up and down (e.g., between the first vertical position and the second vertical position) as the sliding member 120 moves from the first translational position to the second translational position. In some embodiments, the sliding member 120 is made of a polymer, such as polyether ether ketone (PEEK) plastic, polytetrafluoroethylene (PTFE) plastic, or another suitable plastic. Alternatively, the sliding member 120 can be made of a metal such as aluminum.

FIGS. 2C-2E illustrate a perspective views of a push-back assembly 140. The push-back assembly 140 may push against the sliding member 120 to return the sliding member 120 from the second translational position to the first translational position when the interconnect device 104 is removed from the receptacle 102. In some embodiments, a spring mount 146 is rigidly coupled with the receptacle. The pushing member 144 may translationally move with respect to the spring mount 146. The pushing member 144 may include a guide pin 145 that fits into a hole formed in the spring mount 146 to guide movement of the pushing member 144. In some embodiments, springs 142 are coupled with the spring mount 146 and push against the pushing member 144 to impart a spring force on the sliding member 120. In some embodiments, the pushing member 144 forms cutouts to give clearance to coolant lines coupled with the coolant inlet and outlet ports of the cold plate 110. The spring mount 146 may form similar cutouts/features. In some embodiments, the pushing member 144 and/or the spring mount 146 are made of a polymer, such as PEEK plastic, PTFE plastic, or another suitable plastic. Alternatively, the pushing member 144 and/or the spring mount 146 can be made of a metal such as aluminum. Springs 142 may be made of a metal.

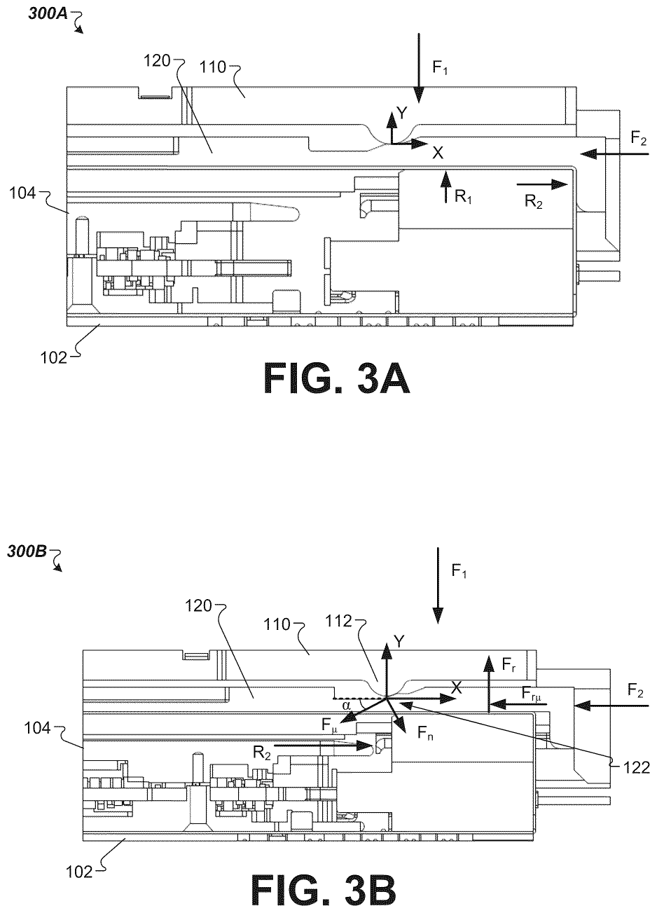

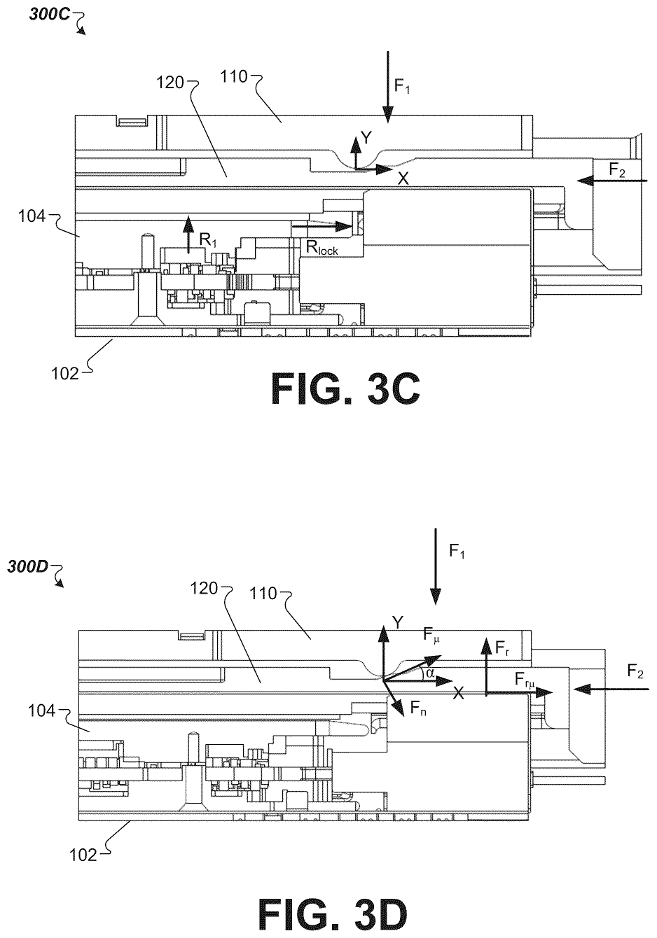

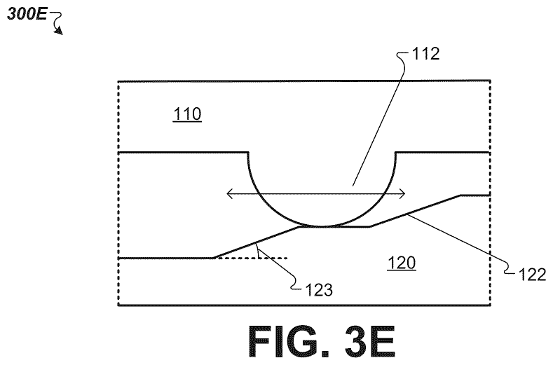

FIGS. 3A-D are side schematic views illustrating forces in a two-position cooling system for an interconnect module, in accordance with at least some embodiments.

FIG. 3A is a side schematic view 300A illustrating forces in a two-position cooling system for an interconnect module. Forces may be shown for when the cold plate 110 is distanced from the interconnect module 104 (e.g., at the first vertical position, at the first distance from the interconnect module 104, etc.). A first spring force F₁ may act upon the cold plate 110 in a negative Y-direction. The cold plate 110 may transfer spring force F₁ to the sliding member 120. A second spring force F₂ may act upon the sliding member 120 in a negative X-direction. The X-axis may be horizontal and the Y-axis may be vertical as shown, or the X-axis may be vertical and the Y-axis may be horizontal. The sliding member 120 may impart reaction forces. In some embodiments, the sliding member 120 imparts a first reaction force R₁ opposite the first spring force F₁ and a second reaction force R₂ opposite the second spring force F₂. In some embodiments, the first spring force F₁ is provided by springs pushing against the cold plate 110 and the second spring force F₂ is provided by spring(s) 142.

The forces along the Y-axis and along the X-axis can be modeled as follows:

$$\sum {F}_{y} : {F}_{1} = {R}_{1}$$

$$\sum {F}_{x} : {F}_{2} = {R}_{2}$$

FIG. 3B is a side schematic view 300B illustrating forces in a two-position cooling system for an interconnect module. Forces may be shown for when the interconnect module 104 is inserted into the receptacle 102. In some embodiments, the interconnect module 104 may be pushed into the receptacle 102 with a force R₂. As the interconnect module 104 contacts the sliding member 120, force R₂ may be transferred to the sliding member 120. Spring(s) 142 may push back against the sliding member 120 with spring force F₂. Springs may push downward on cold plate 110 with spring force F₁. In some embodiments, spring force F₁ is between approximately 10 Newtons and approximately 40 Newtons. In some embodiments, spring force F₁ is approximately 20 Newtons. In some embodiments, spring Force F₂ is between approximately 20 Newtons and approximately 40 Newtons. In some embodiments, spring force F₂ is greater than approximately 25 Newtons. In some embodiments, spring force F₂ is approximately 30 Newtons.

As the skid(s) 112 moves down ramp 122, forces may be exerted between the sliding member 120 and the cold plate (e.g., via the skid(s) 112 and the ramp 122). In some embodiments, the ramp 122 is at an angle α with respect to the X-axis. A normal force Fₙ may be imparted by the skid 112 on the ramp 122. In some embodiments, the normal force Fₙ may be normal to the surface of the ramp 122. A parallel force Fu may be imparted by the skid 112 on the ramp 122. In some embodiments, the parallel force Fu may be in a direction along the surface of the ramp 122 at the angle α with respect to the X-axis. The sliding member 120 may impart reaction forces to the cold plate 110. In some embodiments, the sliding member 120 (via the surface of the ramp 122) imparts a reaction force F_{rμ} in the negative X-direction and reaction force Fᵣ in the positive Y-direction.

The forces along the Y-axis and along the X-axis can be modeled as follows:

$$\sum {F}_{y} : - {F}_{n} cos α - {F}_{μ} sin α + {F}_{1} = 0$$

$$\sum {F}_{x} : - {F}_{2} - {F}_{r μ} + {F}_{n} sin α - {F}_{μ} cos α + {R}_{2} = 0$$

FIG. 3C is a side schematic view 300C illustrating forces in a two-position cooling system for an interconnect module. Forces may be shown for when the interconnect module 104 is fully inserted into the receptacle 102. In some embodiments, a locking mechanism (not illustrated) of the receptacle 102 imparts a locking force R_{lock} on the interconnect module 104 (e.g., to lock the interconnect module 104 in the receptacle). In some embodiments, the interconnect device 104 imparts a reaction force R₁ to the cold plate 110. The reaction force R₁ may be imparted from the top surface of the interconnect device 104 to the cooling surface (e.g., bottom surface) of the cold plate 110.

The forces along the Y-axis and along the X-axis can be modeled as follows:

$$\sum {F}_{y} : {F}_{1} = {R}_{1}$$

$$\sum {F}_{x} : {F}_{2} = {R}_{lock}$$

FIG. 3D is a side schematic view 300D illustrating forces in a two-position cooling system for an interconnect module. Forces may be shown for when the interconnect module 104 is removed from the receptacle 102. As the skid(s) 112 moves up ramp 122, forces may be exerted between the sliding member 120 and the cold plate (e.g., via the skid(s) 112 and the ramp 122). In some embodiments, the ramp 122 is at an angle α with respect to the X-axis. A normal force Fₙ may be imparted by the skid 112 on the ramp 122. In some embodiments, the normal force Fₙ may be normal to the surface of the ramp 122. A parallel force Fu may be imparted by the skid 112 on the ramp 122. In some embodiments, the parallel force Fu may be in a direction along the surface of the ramp 122 at the angle α with respect to the X-axis. The sliding member 120 may impart reaction forces to the cold plate 110. In some embodiments, the sliding member 120 (via the surface of the ramp 122) imparts a reaction force F_{rμ} in the positive X-direction and reaction force Fᵣ in the positive Y-direction.

The forces along the Y-axis and along the X-axis can be modeled as follows:

$$\sum {F}_{y} : - {F}_{n} cos α - {F}_{μ} sinα + {F}_{1} = 0$$

$$\sum {F}_{x} : - {F}_{2} - {F}_{r μ} + {F}_{n} sin α - {F}_{μ} cos α = 0$$

FIG. 3E is a simplified side view 300E of a ramp feature used in a two-position cooling system for an interconnect module, in accordance with at least some embodiments. In some embodiments, a skid 112 moves along the surface of a ramp 122 as the sliding member moves between the first translational position and the second translational position. For example, as the sliding member 120 moves to the right, as shown, the skid may move down the ramp 122, lowering the cold plate 110. As the sliding member 120 moves to the left, the skid may move up the ramp 122, raising the cold plate 110. In some embodiments, the surface of the ramp 122 is at an angle 123 with respect to horizontal frame of reference (e.g., angle 123 is with respect to the receptacle 102). The angle 123 may determine how quickly along the range of travel of the sliding member 120 the cold plate 110 moves to contact the interconnect module 104. If the angle 123 has a higher value, the cold plate moves up and down (e.g., away from or toward the interconnect module 104) quicker (relative to the motion of the sliding member 120) to contact the interconnect module 104. If the angle 123 has a lesser value, the cold plate moves up and down (e.g., away from or toward the interconnect module 104) more slowly. In some embodiments, the surface of the ramp 122 has two stages, each with its own angle. The first stage may be steep to quickly move the cold plate off of the interconnect module and the second stage may be shallow to balance the spring forces without undue stress on the component parts.

In some embodiments, the sliding member 120 can translationally slide (e.g., along the axis of movement, whether that be in a vertical orientation or a horizontal orientation as shown) between approximately 1 mm and approximately 5 mm. The difference between the first translational position (of the sliding member 120) and the second translational position may be between approximately 1 mm and approximately 5 mm. In some embodiments, the cold plate can move (e.g., along an axis of movement orthogonal to the sliding member 120) between approximately 1.5 mm and approximately 2 mm. The difference between the first vertical position (of the cold plate 110) and the second vertical position may be between approximately 1.5 mm and approximately 2 mm. The ratio of distances traveled by the sliding member 120 and the cold plate 110 may depend on the angle 123. In some embodiments, the angle 123 is between approximately 5 degrees and approximately 45 degrees.

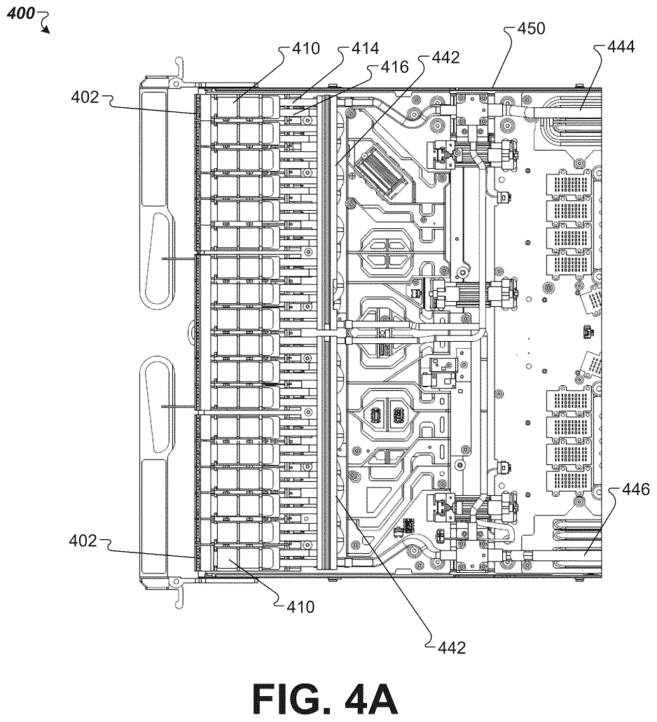

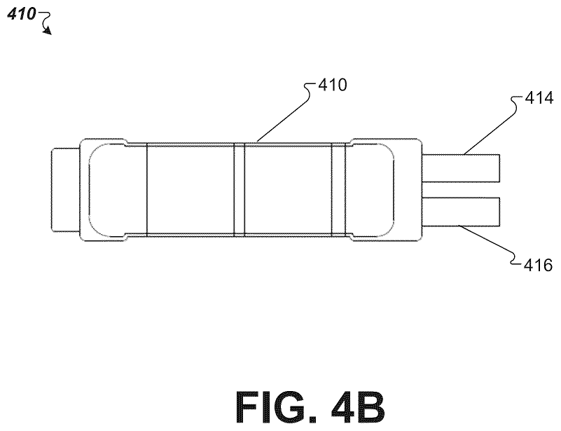

FIG. 4A is a top-down view of a computing tray 400A incorporating a two-position cooling system for an interconnect module, in accordance with at least some embodiments. In some embodiments, the computing tray 400 includes multiple computing components (e.g., GPUs, DPUs, CPUs, switches, and/or interconnect components, etc.) within a chassis 450. The chassis 450 may include sidewalls, a bottom wall, and/or a top wall. Components to cool the computing components, such as cold plates, coolant lines, coolant manifolds, etc., may also be housed within the chassis 450. To connect the computing components with outside computing components (e.g., such as other servers or computing devices, etc.), the chassis 450 includes receptacles 402 each to receive an interconnect module (e.g., interconnect module 104). The receptacles 402 may be situated one next to the other and so on. The interconnect modules may be cooled using cold plates 410.

FIG. 4B is a top-down view of a cold plate 410 for use in a two-position cooling system for an interconnect module, in accordance with at least some embodiments. Referring again to FIG. 4A, in some embodiments, cold plates 410 receive a flow of liquid and/or two-phase coolant. Cool coolant may be received into the chassis 450 via coolant inlet 444. One or more conduits (e.g., coolant lines) may deliver the cool coolant from the inlet to one or more manifolds 442. The coolant may be distributed to the cold plates 410 from the manifolds 442. In some embodiments, coolant flows from a manifold 442 into a cold plate 410 via an inlet 414. The cool coolant received into the cold plate 410 may receive heat from an interconnect module. The warmed coolant may be expelled from the cold plate 410 via an outlet 416. The inlets 414 and outlets 416 may hold the cold plates 410 substantially stationary within the chassis 450. In some embodiments, the expelled warmed coolant may flow to a return manifold 442. In some embodiments, the cold plates 410 are connected in series so that coolant flows from one cold plate 410 to a neighboring cold plate 410 and so on before being collected in the return manifold 442. In some embodiments, the cold plates 410 are connected in parallel so that coolant flows from a cold plate and is collected in the return manifold 442 without flowing to another cold plate 410. The warmed coolant may be collected in a return manifold 442 and directed (e.g., via one or more conduits) to the coolant outlet 446. In some embodiments, the warmed coolant leaves the chassis 450 via the outlet 446 to be cooled, such as in a cooling tower, or a refrigeration unit, etc.

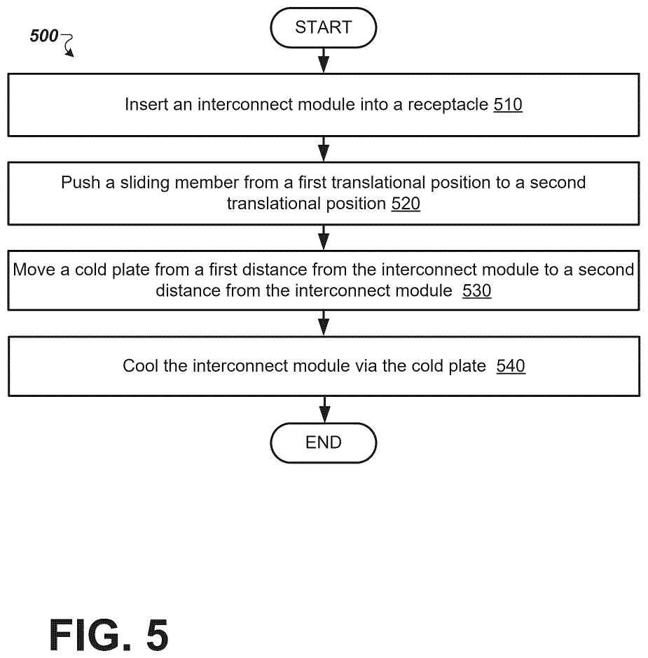

FIG. 5 is a flow diagram of an example method 500 of using a two-position cooling system for an interconnect module, in accordance with at least some embodiments. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 510, an interconnect module is inserted into a receptacle. In some embodiments, the interconnect module is an optical transceiver. The interconnect module may be for sending/receiving electrical and/or optical signals between computing servers or switch trays, etc. In some embodiments, the receptacle is formed in the side of a computing chassis (e.g., a server chassis, a switch tray chassis, etc.). The switches within each layer may be 1U switches, where “1U” refers to the industry-standard size for rack-mounted switches and servers. The switches may be electrical switches, optical switches, hybrid electro-optical switches, or any combination thereof. The switches may be implemented with suitable hardware and/or software that enables the routing of signals in the appropriate domain. For example, an electrical switch may include receivers that receive and convert optical signals into electrical signals for routing within the electrical switch. A receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In some embodiments, receiver/transmitter pairs may be integrated into a single transceiver. Each electrical switch may also include internal switching circuitry for routing electrical signals within the electrical switch.

At operation 520, a sliding member is pushed from a first translational position to a second translational position. In some embodiments, the sliding member is pushed as the interconnect module is inserted into the receptacle. The interconnect module may be inserted a threshold distance into the receptacle before the interconnect module contacts and then pushes the sliding member.

At operation 530, a cold plate is moved (e.g., lowered) from a first distance from the interconnect module (e.g., a first vertical position) to a second distance from the interconnect module (e.g., second vertical position), where a TIM pad on the cold plate is in contact with the interconnect module when the cold plate is the second distance from the interconnect module. In some embodiments, when the sliding member is in the first translational position, the sliding member supports the cold plate away from a surface of the interconnect module at the first distance. A gap may separate the top surface of the interconnect module and a TIM pad on the cooling surface of the cold plate. In some embodiments, the interconnect module can be inserted at least partially into the receptacle without contacting the TIM pad. As the sliding member moves to the second translational position, the sliding member may allow the cold plate to be moved to the second distance. The TIM pad may contact the surface of the interconnect module when the cold plate is at the second distance. In some embodiments, the sliding member forms one or more ramp features upon which skids protruding from the cold plate can slide. When the sliding member moves from the first translational position to the second translational position, the skids may slide along the ramp features, moving the cold plate from the first distance to the second distance.

At operation 540, the interconnect module is cooled via the cold plate. In some embodiments, heat from the interconnect module is provided to the cold plate via the TIM pad on the cooling surface of the cold plate. The heat from the interconnect module may be carried away by coolant flowing through the cold plate.

In some embodiments, upon removal of the interconnect module from the receptacle, the sliding member may move from the second translational position to the first translational position. The skids of the cold plate may slide along the ramp feature(s) of the sliding member, moving the cold plate from the second distance to the first distance, and separating the cold plate from the interconnect module. At the first distance, there may be a gap between the TIM pad on the cooling surface of the cold plate and the surface of the interconnect module. The interconnect module can then be removed from the receptacle without contacting the TIM pad. In some embodiments, the interconnect module can be inserted and removed from the receptacle many times without damaging the TIM pad.

In some embodiments, when the receptacle is oriented horizontally, the first distance (e.g., of the cold plate) corresponds to the first vertical position and the second distance corresponds to the second vertical position as described herein above. Other orientations of the receptacle are possible.

### Servers and Data Centers

The following figures set forth, without limitation, exemplary network server and data center based systems that can be used to implement at least one embodiment.

Datacenters may include multiple network switches in a particular topology, such as a fat tree topology, a slim fly topology, a dragonfly topology, and/or the like. The specifications and makeup of the network switches in the topology affects the overall network performance (e.g., bandwidth capability) of the datacenter. In at least one embodiment, an artificial intelligence (AI) data center infrastructure platform is provided. Examples of an AI data center infrastructure platform are Nvidia® DGX™ SuperPOD™ and DGX™ Foundry. In at least one embodiment, an AI data center infrastructure platform provides accelerated infrastructure and/or scalable performance tailored for AI such as machine learning (ML) and other high-performance computing (HPC) loads.

### Example Data Center Environment

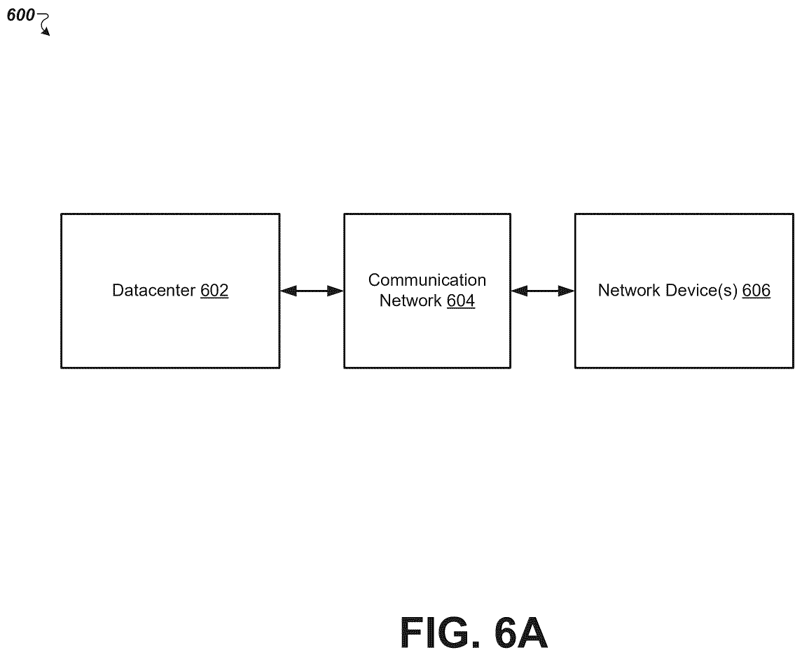

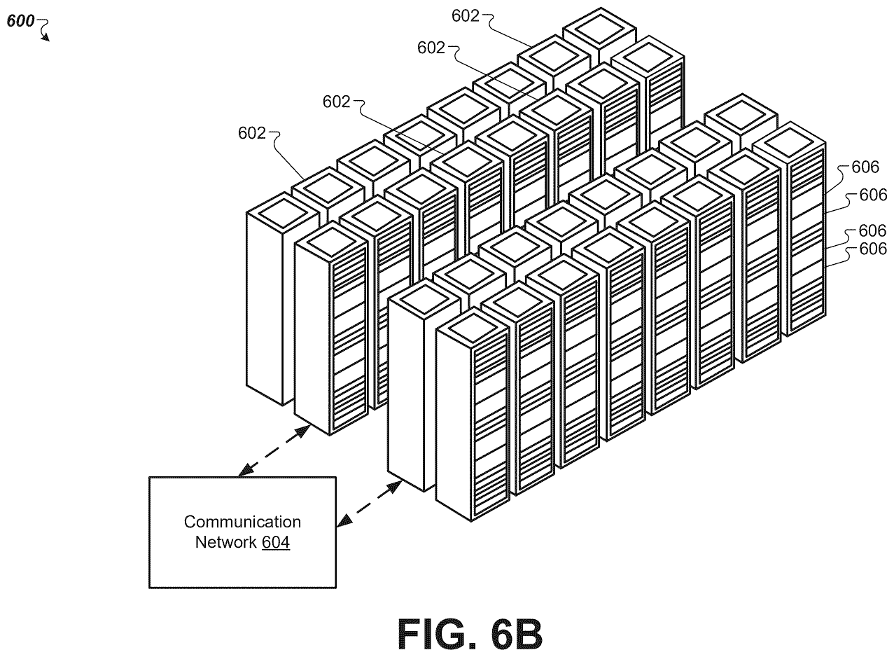

As described above, datacenters, high performance computing clusters, and/or the like are often formed of various computing components or networked devices, and communication networks formed of electrical and/or optical devices may be used to enable communication between the networked devices forming these implementations. With reference to FIGS. 6A-6B, for example, a network architecture 600 may include a datacenter 602, a communication network 604, and network device(s) 606. The network architecture 600 may illustrate a general computing architecture within which more specific systems and/or subsystems may function. Although described hereinafter with reference to a network architecture 600 and/or datacenter 602 within which the embodiments of the present disclosure may be implemented, the present disclosure contemplates that the transceiver resiliency devices and techniques described herein may be applicable to any communication implementation without limitation.

For example, the datacenter 602 may be a centralized facility designed to house computing resources and related components. The datacenter 602 may operate to support the infrastructure required for advanced computational tasks, for efficient, secure, and reliable operations. The datacenter 602 may include the building and structural components, including power supplies, cooling systems, fire suppression systems, and physical security measures that are configured to maintain optimal operating conditions and/or protect the equipment from environmental hazards and unauthorized access. An example datacenter 602 may include high-performance servers or compute nodes, often arranged in racks, such as those illustrated in FIG. 6B, and connected through high-speed networks as described herein. These servers may include processors (e.g., central processing units (CPUs), graphics processing units (GPUs), data processing units (DPUs) and/or the like), memory (e.g., RAM), and storage solutions (e.g., hard disk drives (HDDs), solid state drives (SSDs), and/or the like. The hardware configuration may be designed for parallel processing and high throughput, catering to the demands of high-performance computing (HPC) applications.

The datacenter 602 may include high-speed network equipment, such as network switches, routers, firewalls, and/or the like to facilitate fast and secure data transmission within the datacenter 602 (e.g., between the servers or compute nodes) and between external networks. The datacenter 602 may facilitate communication between servers or compute nodes through a network topology that ensures efficient data exchange, minimizes latency, and maximizes bandwidth. The network topology may dictate how various network devices, such as switches and routers, are interconnected for data flow. By implementing an effective network topology, the datacenter 602 may support high-performance computing tasks. Examples of various network topologies may include hierarchical networking topologies such as the fat tree topology, Slim Fly topology, Dragonfly topology, and/or the like.

The communication network 604 may communicably couple the datacenter 602 with network device(s) 606 and other external devices for data exchange and connectivity. Examples of the communication network 604 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. The ability of the communication network 604 to incorporate multiple network types and configurations may allow the datacenter 602 to adapt to diverse application needs, from general data communication to specialized HPC tasks. As described herein, the communication network 604 may leverage various optical components to establish communication links (e.g., communicably couple) between components in the architecture 600. As such, the communication network 604 may include various optical devices, transceivers, modules, and/or the like that are configured to generate optical signals (e.g., provide optical transmitter functionality) and/or receive optical signals (e.g., provide optical receiver functionality).

The network device(s) 606 may include a variety of computing devices capable of transmitting and receiving signals over the communication network 604. The network device(s) 606 may range from personal computing devices to complex server configurations. Examples include Personal Computers (PCs), laptops, tablets, smartphones, and servers. The network device(s) 606 may facilitate user interactions with the datacenter 602, allowing for data input, retrieval, and processing from remote locations. In addition to individual computing devices, the network device(s) 606 may also include collections of servers or additional datacenters. For instance, these could be other datacenters similar to or the same as datacenter 602. Such an interconnection may allow for the formation of a distributed computing environment for improved redundancy, load balancing, and disaster recovery capabilities. By linking multiple datacenters, the network architecture 600 may leverage geographically dispersed resources, optimizing performance and ensuring high availability.

As described herein, the datacenter 602 and/or the network device(s) 606 may include storage devices and processing circuitry for executing computing tasks, such as controlling the flow of data internally and over the communication network 604. The processing circuitry may include software, hardware, or a combination thereof. For example, the processing circuitry may include a memory containing executable instructions and a processor (e.g., a microprocessor) that executes these instructions. The memory may correspond to any suitable type of memory device or collection of memory devices configured to store instructions. Non-limiting examples of suitable memory devices include Flash memory, Random Access Memory (RAM), Read Only Memory (ROM), variants thereof, combinations thereof, or similar technologies. In specific embodiments, the memory and processor may be integrated into a common device, such as a microprocessor with integrated memory. Additionally, or alternatively, the processing circuitry may comprise hardware components, such as an application-specific integrated circuit (ASIC). Other non-limiting examples of processing circuitry include Integrated Circuit (IC) chips, CPUs, GPUs, quantum processing units (QPUs), a plurality of parallel processing units (PPUs), microprocessors, Field Programmable Gate Arrays (FPGAs), collections of logic gates or transistors, resistors, capacitors, inductors, and diodes. Some or all of the processing circuitry may be provided on a Printed Circuit Board (PCB) or a collection of PCBs. It should be appreciated that any appropriate type of electrical component or collection of electrical components may be suitable for inclusion in the processing circuitry. QPUs configured to perform one or more operations associated with a quantum algorithm In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

In addition, although not explicitly shown, the present disclosure contemplates that the datacenter 602 and network device(s) 606 may include one or more communication interfaces for facilitating wired and/or wireless communication between one another and other unillustrated elements of the network architecture 600. These communication interfaces may include a variety of technologies, including but not limited to Ethernet ports, fiber optic connections, Wi-Fi® transceivers, Bluetooth® modules, and cellular communication modules for integration and interoperability among the various components within the network architecture 600.

Furthermore, the present disclosure contemplates that the network architecture 600 may include additional components and functionalities. For example, the network architecture may include, without limitation, additional processing units, specialized accelerators (such as Tensor Processing Units or TPUs), enhanced security modules, and redundant power supplies. The inclusion of these elements may be intended to ensure that the network architecture 600 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the network architecture 600.

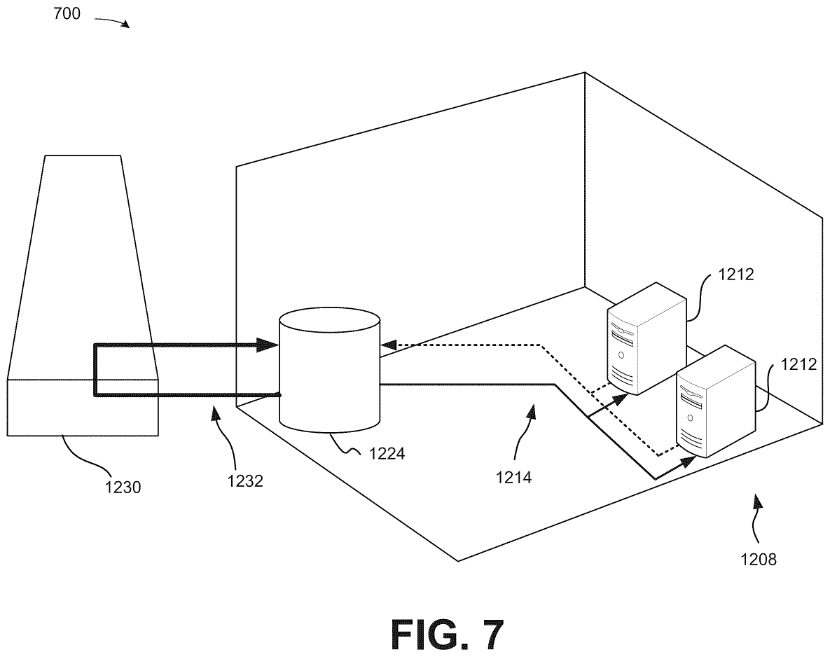

FIG. 7 illustrates an example datacenter cooling system 1200, according to at least some embodiments. In at least one embodiment, system 1200 includes a datacenter 1208 having one or more servers 1212. In at least one embodiment, servers 1212 are rack-based servers. For example, servers 1212 are disposed in one or more racks of datacenter 1208. In at least one embodiment, as discussed above with reference to FIG. 1, each server 1212 includes multiple computing components and/or interconnect modules. In at least one embodiment, a server 1212 includes one or more computing components having greater than a threshold power density. Power density may be used to describe component power relative to component size. Computing components having greater than a threshold power density may be referred to as high-power computing components. In at least one embodiment, a high-power computing component may be a processing unit such as a central processing unit (CPU) or a graphical processing unit (GPU). In at least one embodiment, a high-power computing component may include a specialized or general processing device, such as aforementioned GPU and CPU, a field programmable gate array (FPGA), a data processing unit (DPU), and so on. In at least one embodiment, a high-power computing component of a server 1212 may put out more than a threshold amount of heat. Similarly, in at least one embodiment, a server 1212 includes one or more computing components having less than a threshold power density. Computing components having less than a threshold power density may be referred to as low-power computing components. In at least one embodiment, a low-power computing component of a server 1212 may output less than a threshold amount of heat. In at least one embodiment, low-power computing components of a server may include a power supply, a motherboard, memory, a network interface controller (NIC), a solid state drive or hard drive, an audio card, and so on.

In at least one embodiment, computing components and/or interconnect modules of servers 1212 are cooled by one or more cooling loops. In at least one embodiment, first cooling loop 1214 flows a first coolant to servers 1212 to cool one or more computing components and/or interconnect modules of the servers 1212. In at least one embodiment, cooling loop 1214 includes conduits such as piping and/or tubing to flow coolant between a cooling distribution unit (CDU) 1224 and servers 1212. In at least one embodiment, first cooling loop 1214 may flow coolant along pipes, tubing, and/or one or more manifolds from first CDU 1224 to servers 1212 and back to first CDU 1224. In at least one embodiment, a first coolant may carry heat from servers 1212 to CDU 1224. In at least one embodiment, first coolant is provided to a cooling device (e.g., a cold plate) in servers 1212 for cooling an interconnect module as described herein.

In at least one embodiment, a cold plate is a metal plate that can be attached to an electronic device (e.g., a computing component) such as a CPU or a GPU. In at least one embodiment, a cold plate is attached to an electronic device by an adhesive such as a thermal epoxy. In at least one embodiment, a cold plate is attached to an electronic device by one or more mechanical fasteners. In at least one embodiment, a cold plate is supported by a sliding member and/or lowered by the sliding member to contact an interconnect module as described herein. In at least one embodiment, a cold plate can implement localized cooling of powered electronics by transferring heat from an electronic device to a liquid coolant that flows to a remote heat exchanger. In at least one embodiment, a cold plate includes a thick metal plate having one or more internal passages through which liquid coolant can flow. In at least one embodiment, a cold plate can be made of a material such as aluminum, steel, stainless steel, or copper. In at least one embodiment, an electronic device in contact with a cold plate is cooled by conduction. Heat from an electronic device may conduct from a device to an attached cold plate. Heat may be carried away by liquid coolant flowing through a cold plate.

In at least one embodiment, first coolant is an electrically conductive coolant. In at least one embodiment, first coolant can include water, deionized water, or a refrigerant such as R-134a, R-1234YF, 515B, or any low-global warming potential (GWP) coolant or any per- and polyfluoroalkyl (PFAs)-compliant coolant. In at least one embodiment, first coolant includes a mixture of water and additives such as a water and ethylene glycol mixture or a water and propylene glycol mixture. In at least one embodiment, first coolant includes a 25% concentration of propylene glycol in deionized water. Heat from high-power computing components is carried by first coolant to first CDU 1224. In at least one embodiment, first cooling loop 1214 includes one or more supply conduits (represented by solid lines) and one or more return conduits (represented by dashed lines). In at least one embodiment, first coolant is a single-phase coolant. In at least one embodiment, first coolant is a dual-phase coolant. In at least one embodiment, first coolant may not vaporize when heated by first computing components.

In at least one embodiment, CDU 1224 includes a heat exchanger to exchange heat between first cooling loop 1214 and a second cooling loop 1232. In at least one embodiment, second cooling loop 1232 flows another coolant, such as water, from CDU 1224 to a cooling tower 1230 to exchange heat from first cooling loop 1214 with an ambient environment. In at least one embodiment, second cooling loop 1232 flows coolant from CDU 1224 to one or more chillers to exchange heat with a cold sink such as an ambient environment. In at least one embodiment, an ambient environment includes an air environment or a liquid environment. In at least one embodiment, CDU 1224 includes one or more pumps to pump first coolant and/or another coolant of second cooling loop 1232. In at least one embodiment, CDU 1224 includes a controller to control flow and/or distribution of coolant along first cooling loop 1214 and/or second cooling loop 1232. In at least one embodiment, CDU 1224 includes one or more valves to effectuate such control. In at least one embodiment, second cooling loop 1232 may be referred to as a “primary” cooling loop, while first cooling loop 1214 may be referred to as a “secondary” cooling loop.

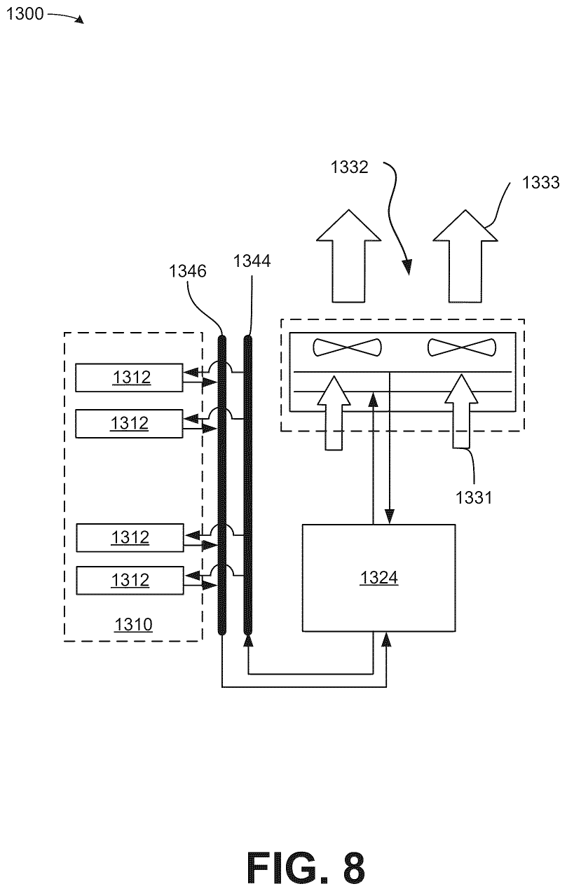

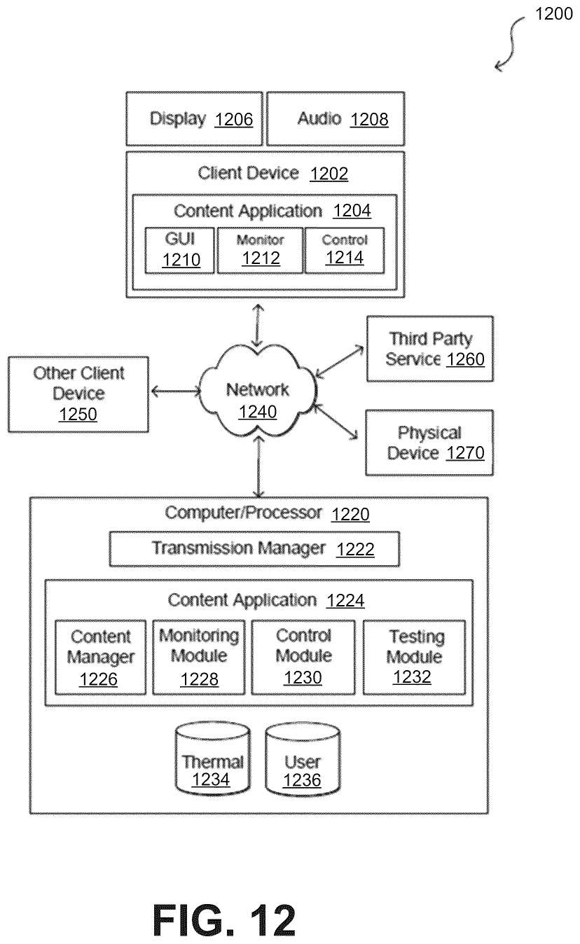

FIG. 8 illustrates a schematic diagram of a datacenter cooling system 1300, according to at least some embodiments. Features illustrated in FIG. 8 having similar numbering to features shown in FIG. 12 may have similar functions. In at least one embodiment, system 1300 includes multiple servers 1312 disposed in a datacenter rack 1310. In at least one embodiment, servers 1312 are a part of a datacenter having multiple racks 1310, each rack supporting multiple servers 1312. Although only one rack 1310 is shown in FIG. 8, system 1300 can provide cooling for servers 1312 in multiple racks 1310.

In at least one embodiment, first coolant is flowed along one or more flow paths of one or more first cooling loops from CDU 1324 to servers 1312. In at least one embodiment, first coolant is flowed through one or more manifolds. In at least one embodiment, a supply manifold 1344 is supplied with first coolant from CDU 1324. In at least one embodiment, supply manifold 1344 may distribute first coolant to multiple servers 1312 supported in rack 1310. In at least one embodiment, first coolant may flow from supply manifold 1344 into servers 1312 to cool high-power computing component(s) and/or interconnect module(s) of servers 1312. First coolant may flow to one or more cold plates in servers 1312 and/or to one or more cooling devices for cooling interconnect modules as described herein.

In at least one embodiment, high-power computing components and/or interconnect devices within servers 1312 may each be coupled to one or more cold plates to receive first coolant. In at least one embodiment, one or more cold plates may transfer heat from a high-power computing component or an interconnect module to first coolant. In at least one embodiment, first coolant carries heat away from high-power computing components and/or interconnect modules of servers 1312. In at least one embodiment, a return manifold 1346 collects heated first coolant output from each of servers 1312. In at least one embodiment, first coolant flows from return manifold 1346 to CDU 1324, where first coolant is cooled by chilled water or other coolant flowing between chiller 1332 and CDU 1324. In at least one embodiment, heat may be exchanged between first coolant and cooled water or other coolant in a liquid-to-liquid heat exchanger within CDU 1324. In at least one embodiment, cooled first coolant is again flowed from CDU 1324 to servers 1312 via supply manifold 1344.

In at least one embodiment, water or another coolant flows between chiller 1332 and CDU 1324 via a second cooling loop. In at least one embodiment, cool air 1331 is drawn into chiller 1332 by one or more fans. In at least one embodiment, water, or another coolant, carrying heat transferred from first cooling loop (e.g., via heat exchangers in CDU 1324), is cooled by cool air 1331. In at least one embodiment, heat from water or another coolant is transferred to air, and heated air 1333 is forced out of chiller 1332 (by one or more fans). In at least one embodiment, water or another coolant is therefore cooled by air. In at least one embodiment, cooled water flows back to CDU 1324 along a flow path of a second cooling loop.

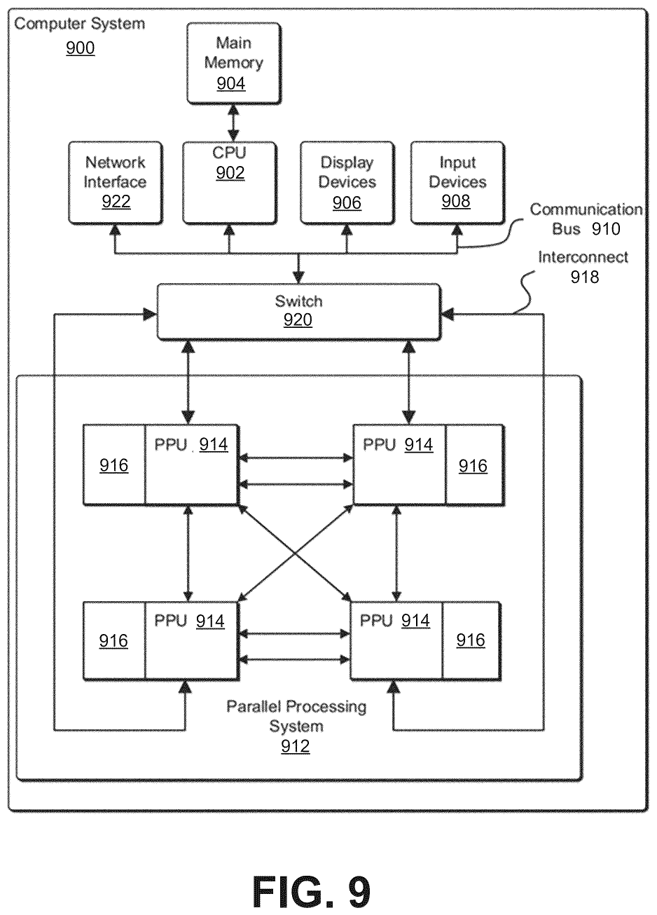

FIG. 9 illustrates a computer system 900, according to at least one embodiment. In at least one embodiment, computer system 900 is configured to implement various processes and methods described throughout this disclosure.

In at least one embodiment, computer system 900 comprises, without limitation, at least one central processing unit (“CPU”) 902 that is connected to a communication bus 910 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 900 includes, without limitation, a main memory 904 and control logic (e.g., implemented as hardware, software, or a combination thereof) and data are stored in main memory 904 which may take form of random access memory (“RAM”). In at least one embodiment, a network interface subsystem (“network interface”) 922 provides an interface to other computing devices and networks for receiving data from and transmitting data to other systems from computer system 900.

In at least one embodiment, computer system 900, in at least one embodiment, includes, without limitation, input devices 908, parallel processing system 912, and display devices 906 which can be implemented using a conventional cathode ray tube (“CRT”), liquid crystal display (“LCD”), light emitting diode (“LED”), plasma display, or other suitable display technologies. In at least one embodiment, user input is received from input devices 908 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 904 and/or secondary storage. Computer programs, if executed by one or more processors, enable system 900 to perform various functions in accordance with at least one embodiment. memory 904, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 902; parallel processing system 912; an integrated circuit capable of at least a portion of capabilities of both CPU 902; parallel processing system 912; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 900 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 912 includes, without limitation, a plurality of parallel processing units (“PPUs”) 914 and associated memories 916. In at least one embodiment, PPUs 914 are connected to a host processor or other peripheral devices via an interconnect 918 and a switch 920 or multiplexer. In at least one embodiment, parallel processing system 912 distributes computational tasks across PPUs 914 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 914, although such shared memory may incur performance penalties relative to use of local memory and registers resident to a PPU 914. In at least one embodiment, operation of PPUs 914 is synchronized through use of a command such as_syncthreads( ), wherein all threads in a block (e.g., executed across multiple PPUs 914) to reach a certain point of execution of code before proceeding.

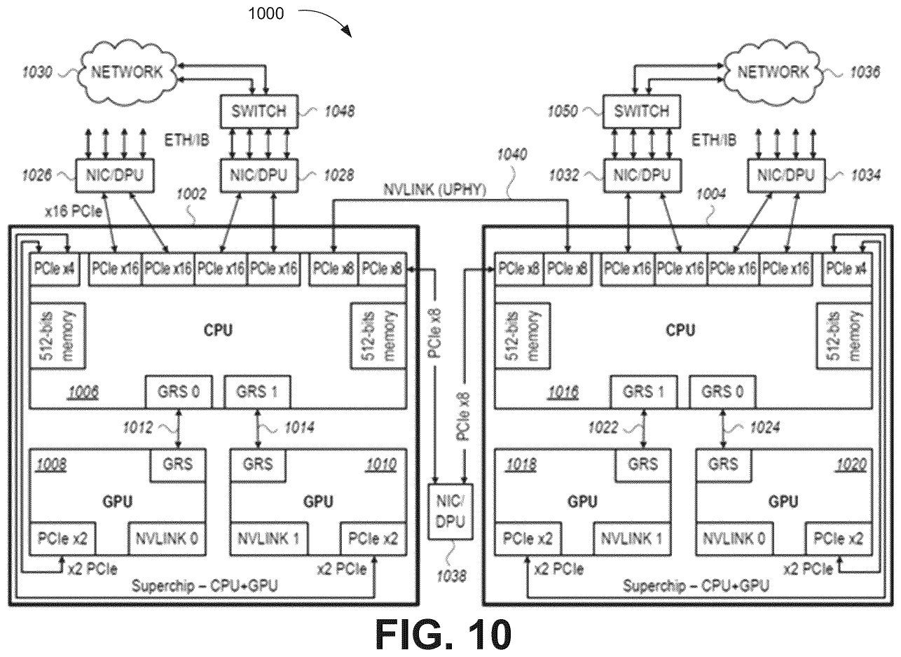

FIG. 10 is a block diagram that schematically illustrates a computing system 1000, e.g., a data center or a High-Performance Computing (HPC) cluster, in accordance with an embodiment that is described herein. System 1000 comprises a plurality of subsystems, e.g. multiple processing devices coupled to each other, multiple network devices, and multiple networks, according to at least one embodiment. Computing system 1000 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1000 and to one or more external networks 1030, 1036. In the present example, system 1000 comprises a packet switch 1048 that connects NIC/DPU 1028 to network 1030, and a packet switch 1050 that connects NIC/DPU 1032 to network 1036.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1000 can include one or more CPUs and one or more GPUs.

FIG. 10 also demonstrates an example architecture of a multi-GPU architecture. As illustrated in the figure, computing system 1000 includes a processing device 1002 with a multi-GPU architecture. In particular, processing device 1002 may be a system-on-chip and includes multiple subsystems such as a CPU 1006, a GPU 1008, and a GPU 1010. CPU 1006 can be coupled to GPU 1008 via a die-to-die (D2D) or chip-to-chip (C2C) interconnect 1012, such as a Ground-Referenced Signaling interconnect (GRS interconnect). CPU 1006 can be coupled to GPU 1010 via a D2D or C2C interconnect 1014. CPU 1006 can also couple to GPU 1008 and GPU 1010 via PCIe interconnects.

CPU 1006 can be coupled to one or more NICs or DPUs, which are coupled to one or more networks. For example, as illustrated in FIG. 10, CPU 1006 is coupled to a first NIC/DPU 1026, which is coupled to a network 1030. CPU 1006 is also coupled to a second NIC/DPU 1028, which is coupled to network 1030 via switch 1048. NIC/DPU 1026 and NIC/DPU 1028 can be coupled to network 1030 over Ethernet (ETH), NVLINK or InfiniBand (IB) connections, for example.

Computing system 1000 also includes a processing device 1004 with a multi-GPU architecture. In particular, processing device 1004 includes multiple subsystems including a CPU 1016, a GPU 1018, and a GPU 1020. CPU 1016 can be coupled to GPU 1018 via an D2D or C2C interconnect 1022. CPU 1016 can be coupled to GPU 1020 via a D2D or C2C interconnect 1024. CPU 1016 can also couple to GPU 1018 and GPU 1020 via PCIe interconnects. CPU 1016 can be coupled to one or more NICs or DPUs, which are coupled to one or more networks. For example, as illustrated in FIG. 10, CPU 1016 is coupled to a first NIC/DPU 1032, which is coupled to a network 1036. CPU 1016 is also coupled to a second NIC/DPU 1034, which is coupled to network 1036 via switch 1050. NIC/DPU 1032 and NIC/DPU 1034 can be coupled to network 1036 over Ethernet (ETH), NVLINK or InfiniBand (IB) connections.

In at least one embodiment, processing device 1002 and processing device 1004 can communication with each other via a NIC/DPU 1038, such as over PCIe interconnects. Processing device 1002 and processing device 1004 can also communicate with each other over a high-bandwidth communication interconnects 1040, such as an NVLink interconnect or other high-speed interconnects. The packet switches in FIG. 10 may comprise, for example, Nvidia Quantum-2 switches. The NICs/DPUs in the figure may comprise, for example, Nvidia Bluefield DPUs.

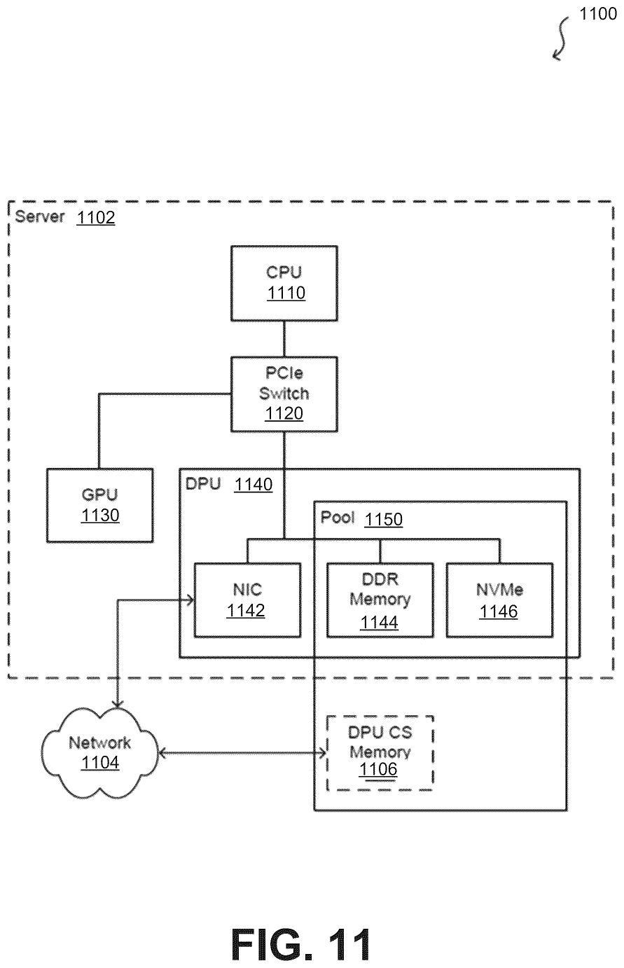

FIG. 11 illustrates an example computing environment, in accordance with at least one embodiment.

FIG. 11 illustrates an example computing environment 1100 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 1100 may include a server 1102 which may be used to perform HPC workloads, such as AI training or machine learning model training. In an embodiment, the server 1102 may be an application instance or a compute node. The server 1102 may include a CPU 1110 associated with a switch 1120, such as a peripheral component interconnect express (PCIe) switch, which may control at least some data transmission over communication paths interconnecting various components. In an embodiment, the CPU 1110 may include a root complex processor.

The PCIe switch 1120 may also be associated with a GPU 1130 and a DPU 1140, and may transmit data between at least some of the CPU 1110, the GPU 1130, the DPU 1140, and other components. In an embodiment, the PCIe switch 1120 may be associated with more than one GPU or more than one DPU. In another embodiment, the PCIe switch 1120 may be located within the DPU 1140. The PCIe switch 1120 may manage the transfer of at least some data between the CPU 1110, the GPU 1130, and the DPU 1140. In another embodiment, the number of GPUs associated with the PCIe switch 1120 may be equal to the number of DPUs associated with the PCIe switch 1120. In at least one embodiment, the server 1102 may include, without limitation, any number of the CPUs 1110, the PCIe switches 1120, the GPUs 1130, and/or the DPUs 1140, in any combination. For example, in at least one embodiment, server 1102 could include eight, sixteen, thirty-two, and/or more GPUs 1130. In at least one embodiment, communication paths interconnecting various components, including but not limited to the CPU 1110, the PCIe switch 1120, the GPU 1130, and the DPU 1140, in FIG. 11 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 1140 may include a network interface controller (NIC) 1142, a DDR memory 1144, and a non-volatile memory express (NVMe) device 1146. The NIC 1142 may be able to interface with a network 1104, which may also interface with additional NVMe devices available to the DPU 1140, such as over fabric. In an embodiment, the DPU 1140 may not include the NVMe device 1146. In another embodiment, the NVMe device 1146 may be located on the server 1102 and not on the DPU 1140. In yet another embodiment, the computing environment 1100 may include more than one of the NVMe device 1146, such as a first NVMe device in the DPU 1140 and a second first NVMe device on the server 1102 an associated directly with the PCIe switch 1120. In an embodiment, the DPU 1140 may not include the DDR memory 1144 and may include a computational storage services (CSS) in place of, or in addition to, the DDR memory 1144. For example, computing environment 1100 may include DPU computational storage (CS) memory 1106 available to the DPU 1140 as part of the CSS. The network 1104 may be able to interface with the DPU CS memory 1106 through the NIC 1142, according to any suitable interface protocol, such as remote direct memory access (RDMA) over Ethernet, InfiniBand, Fiber Channel, etc.

The total memory of the computing environment 1100 available for data storage may be expanded through the use of the DPU 1140 on nodes of the system. The DPU 1140 may have access to a pool 1150 of memory already available to the server 1102, such as double data rate (DDR) memory, on-board NVMe devices, NVMe devices over fabric, and CS. The pool 1150 of memory may include at least one of the DDR memory 1144, NVMe 1146, and the DPU CS memory 1106. The DPU 1140 may also be able to access the available memory of other DPUs as part of the pool 1150, and other DPUs may be able to access the available memory of DPU 1140, such as the pool 1150. This available memory can be accessed and utilized for data storage, without the addition of compute resources, such as compute nodes, which would be required using other solutions. The available pool 1150 accessible to the DPU 1140 may be provisioned for the server 1102 to expand the total memory available for data storage, such as to reduce the data storage load on the CPU 1110 or the GPU 1130, which can instead increase the utilization of their memory for processing. For example, during training of an AI, the model states, residual states, activation functions, and checkpoints can be stored, or offloaded, on the pool 1150 accessible to the DPU 1140.

FIG. 12 illustrates an example network configuration 1200 of components that can be used to implement aspects of various embodiments, such as to provide, generate, modify, encode, process, fuse, and/or transmit generated image data, calculated measurements, or other such content. In at least one embodiment, a client device 1202 can generate or receive data for a session using components of a content application 1204 on the client device 1202 and data stored locally on that client device. In at least one embodiment, a content application 1224 executing on a computer or processor 1220 (e.g., a cloud server or control system) may initiate a session associated with at least one client device 1202 (e.g., a vehicle or robot), as may use a session manager and user data stored in a user database 1236, and can cause content such as liquid coolant or server thermal data to be selected and/or retrieved from a repository 1234 to be used by a testing module 1232 to calculate one or more performance metrics for a monitoring module 1228, which can provide flow data or thermal data to a control module 1230 to control a flow or temperature, in an environment where the data is to be used to determine appropriate operation. A content manager 1226 may work with at these various modules to perform testing and analysis, and potentially instruct any actions to be taken in response to a performance metric failing to satisfy an operational requirements. At least a portion of this data or instructional content can be transmitted to the client device 1202 and/or a physical device 1270 using an appropriate transmission manager 1222 to send by download, streaming, or another such transmission channel. An encoder may be used to encode and/or compress at least some of this data before transmitting to the client device 1202. In at least one embodiment, the client device 1202 receiving such content can provide this content to a corresponding content application 1204, which may also or alternatively include a graphical user interface 1210, a flow monitor module 1212, and a control module 1214 for use in providing, synthesizing, rendering, compositing, modifying, or using content for presentation, navigation, control, (or other purposes) on or by the client device 1202, such as may be transmitted to the physical device 1270. In some embodiments, the computer/processor 1220 and client device 1202 may be able to communicate directly without needing to transmit data over a network 1240, in order to avoid issues with latency and availability, etc., A decoder may also be used to decode data received over the network 1240 for presentation via client device 1202, such as imaging content or performance metrics through a display device 1206 and audio, such as corresponding sounds or synthesized speech, through at least one audio playback device 1208, such as speakers or headphones. In at least one embodiment, at least some of this content may already be stored on, rendered on, or accessible to client device 1202 such that transmission over a network 1240 is not required for at least that portion of content, such as where that content (e.g., thermal data) may have been previously downloaded or stored locally on a hard drive or optical disk. In at least one embodiment, a transmission mechanism such as data streaming can be used to transfer this content from the computer/processor 1220, or user database 1236, to the client device 1202. In at least one embodiment, at least a portion of this content can be obtained, enhanced, and/or streamed from another source, such as a third party service 1260 or other client device 1250, that may also include a content application for generating, updating, enhancing, or providing map content. In at least one embodiment, portions of this functionality can be performed using multiple computing devices, or multiple processors within one or more computing devices, such as may include a combination of CPUs and GPUs (Graphics Processing Unit).

In at least some of these examples, client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a data center or server farm. In at least one embodiment, the request may be received or processed by at least one edge server, that sits on a network edge and is outside at least one security layer associated with the cloud provider environment. In this way, latency can be reduced by allowing the client devices to interact with servers that are in closer proximity, while also improving security of resources in the cloud provider environment.

In at least one embodiment, such a system can be used for monitoring or managing thermal conditions of a server which includes cold plates as liquid manifolds. In other embodiments, such a system can be used for other purposes, such as for providing control of liquid coolant flow, or for performing deep learning operations. In at least one embodiment, such a system can be implemented using an edge device or may incorporate one or more Virtual Machines (VMs). In at least one embodiment, such a system can be implemented at least partially in a data center or at least partially using cloud computing resources.

### Cold Plate

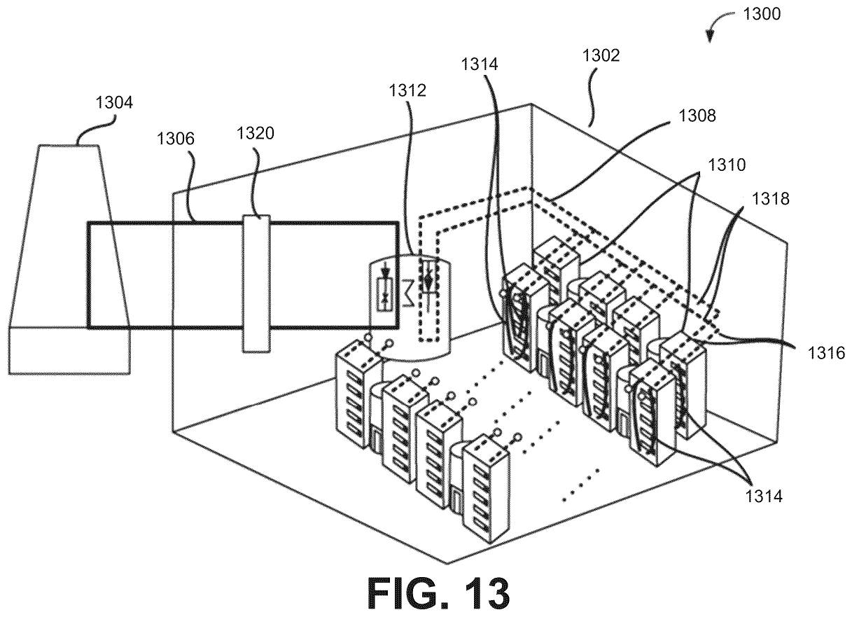

FIG. 13 illustrates an example datacenter cooling system 1300, according to at least some embodiments. In at least one embodiment, a cold plate includes adjustable fins forming microchannels for fluid to flow through. In at least one embodiment, fins in a cold plate enable transfer of heat from at least one associated computing device to a fluid flowing through microchannels formed between multiple fins. In at least one embodiment, fins of a cold plate are dynamically and adjustable in real time to allow transfer of more heat from at least one computing device to a fluid that flows through a cold plate having fins. In at least one embodiment, such fins may be adjusted by a processor or processorless system based in part on a temperature determined, such as sensed, for a cold plate. In at least one embodiment, a temperature may be associated with at least one computing device, a workload of at least one computing device, or a fluid at different time periods and at an entry, and at an egress of a cold plate. In at least one embodiment, a processorless system may rely on a thermal property of at least two materials used to form fins for a cold plate so that such fins may react without a processor to cause exposure of more surface area to a fluid. In at least one embodiment, such fins may include an overlapping portion that may be caused to be exposed by action of a control mechanism or by properties of at least two materials associated together to form a fin.

### Cooling System

In at least one embodiment, an exemplary datacenter 1300 can be utilized as illustrated in FIG. 13, which has a cooling system subject to improvements described herein. In at least one embodiment, numerous specific details are set forth to provide a thorough understanding, but concepts herein may be practiced without one or more of these specific details. In at least one embodiment, datacenter cooling systems can respond to sudden high heat requirements caused by changing computing-loads in present day computing components. In at least one embodiment, as these requirements are subject to change or tend to range from a minimum to a maximum of different cooling requirements, these requirements must be met in an economical manner, using an appropriate cooling system. In at least one embodiment, for moderate to high cooling requirements, liquid cooling system may be used. In at least one embodiment, high cooling requirements are economically satisfied by localized immersion cooling. In at least one embodiment, these different cooling requirements also reflect different heat features of a datacenter. In at least one embodiment, heat generated from these components, servers, and racks are cumulatively referred to as a heat feature or a cooling requirement as cooling requirement must address a heat feature entirely.

In at least one embodiment, a datacenter liquid cooling system is disclosed. In at least one embodiment, this datacenter cooling system addresses heat features in associated computing or datacenter devices, such as in graphics processing units (GPUs), in switches, in dual inline memory module (DIMMs), or central processing units (CPUs). In at least one embodiment, these components may be referred to herein as high heat density computing components. Furthermore, in at least one embodiment, an associated computing or datacenter device may be a processing card having one or more GPUs, switches, or CPUs thereon. In at least one embodiment, each of GPUs, switches, and CPUs may be a heat generating feature of a computing device. In at least one embodiment, a GPU, a CPU, or a switch may have one or more cores, and each core may be a heat generating feature.

In at least one embodiment, a cold plate includes adjustable fins forming microchannels for fluid to flow through. In at least one embodiment, fins in a cold plate enable transfer of heat from at least one associated computing device to a fluid flowing through microchannels formed between multiple fins. In at least one embodiment, fins of a cold plate are dynamically and adjustable in real time to allow transfer of more heat from at least one computing device to a fluid that flows through a cold plate having fins. In at least one embodiment, such fins may be adjusted by a processor or processorless system based in part on a temperature determined, such as sensed, for a cold plate. In at least one embodiment, a temperature may be associated with at least one computing device, a workload of at least one computing device, or a fluid at different time periods and at an entry, and at an egress of a cold plate. In at least one embodiment, a processorless system may rely on a thermal property of at least two materials used to form fins for a cold plate so that such fins may react without a processor to cause exposure of more surface area to a fluid. In at least one embodiment, such fins may include an overlapping portion that may be caused to be exposed by action of a control mechanism or by properties of at least two materials associated together to form a fin.

In at least one embodiment, a cold plate has a top plate, a bottom plate, and fins in between In at least one embodiment, a bottom plate may be a base of a cold plate. In at least one embodiment, a top plate may be intermediary between a cover plate of a cold plate and a bottom or base plate of a cold plate. In at least one embodiment, fins may be coupled to a bottom or base plate and to a top plate so that a top plate may be moved to uncover an overlapping portion of each fin and expose an overlapping portion of each fin to fluid flowing through a cold plate. In at least one embodiment, exposure of an overlapping portion of each fin results in surface area previously covered to be exposed to fluid and to provide additional cooling of fins of a cold plate, and by association, of an associated computing device.

In at least one embodiment, multiple fins form microchannels for fluid to flow therebetween. In at least one embodiment, such fins are able to actively or passively react to thermal feedback by a modification of microchannels to enable fluid to absorb more heat from at least one computing device. In at least one embodiment, an active reaction may be enabled by at least one processor that can expose more surface area of such fins by expanding an overlapping portion of such fins. In at least one embodiment, a passive reaction may be enabled by a thermal property of materials associated together to form each fin of such fins that allows such fins to expand.

In at least one embodiment, issues of cold plates being static devices are addressed by intelligent and dynamic cold plates herein. In at least one embodiment, an intelligent and dynamic cold plate allows a cold plate (via its internal features) to react to sensed or determined temperature from at least one computing device. In at least one embodiment, compared to static cold plates, intelligence aspects of an intelligent and dynamic cold plate allow sensor inputs to be used to modify provided fins of such a cold plate. In at least one embodiment, microchannels formed by such fins are able to be changed to cause a change in a fluid path or to increase interaction surfaces between a fluid and each such fin. In at least one embodiment, such aspects allow more fluid to pass through to certain areas or to pass through certain areas and allow heat removal in those areas where high heat density occurs from at least one computing device.

In at least one embodiment, static cold plates used for liquid cooling of GPU, CPU, Switches, and other high heat density components may have static microchannels allowing flow of fluid therein to remove heat from such heat dissipating components in datacenters. In at least one embodiment, static cold plates incorporate design and methods for heat removal that are not related to or reactive to heat density or heat dissipation by computing components. In at least one embodiment, some cold plates may have varying thermal behaviors depending on computational, environmental and other attributes that require a dynamic behavior for achieving optimum heat removal capability for available resources in a liquid cooled environment.

In at least one embodiment, an indirect cooling cold plate, which is liquid-cooled, may be composed of parts therein. In at least one embodiment, two parts may be provided so that a bottom or base layer or part provides a rigid mechanical attachment and also works as a highly thermal conductive medium where heat is conducted from computing components (GPU, Switch, and CPU) to multiple fins forming microchannels over a bottom or base plate or part. In at least one embodiment, such fins are built into a base metal and may be associated with a top or upper plate or part, which is an intermediary plate or part. In at least one embodiment, a top or upper plate or part that is an intermediary plate or part is non-conductive and made of a non-conductive material. In at least one embodiment, a cover plate encloses (with side plates) such parts within an intelligent and dynamic cold plate.

In at least one embodiment, a top or upper plate or part, by its intermediary plate or part function, is able to dynamically modify a base plate's microchannel fluid path based in part on an instantaneous thermal behavior of heating components associated with an intelligent and dynamic cold plate. In at least one embodiment, using intelligent sensing, inferencing and adaptive modification, microchannels forming fluid paths may be dynamically adjusted to cause or rush more fluid (for heat removal) to areas of high heat density within an intelligent and dynamic cold plate. In at least one embodiment, such features also enable simultaneous reduction of fluids flow to block microchannels for areas where there is less demand for heat removal determined or sensed from a base plate of an intelligent and dynamic cold plate. In at least one embodiment, an overlapping portion of provided fins within an intelligent and dynamic cold plate may be used to block or restrict microchannels by being thicker at an overlapping portion between fins of an intelligent and dynamic cold plate. In at least one embodiment, multiple top plates may be provided to function as intermediary plates and may each be associated with different fins. In at least one embodiment, movement of different top plates achieve different blocks or restrictions or flow redirection within an intelligent and dynamic cold plate.

In at least one embodiment, an exemplary datacenter 1300 can be utilized as illustrated in FIG. 13, which has a cooling system subject to improvements described herein. In at least one embodiment, a datacenter 1300 may be one or more rooms 1302 having racks 1310 and auxiliary equipment to house one or more servers on one or more server trays. In at least one embodiment, a datacenter 1300 is supported by a cooling tower 1304 located external to a datacenter 1300. In at least one embodiment, a cooling tower 1304 dissipates heat from within a datacenter 1300 by acting on a primary cooling loop 1306. In at least one embodiment, a cooling distribution unit (CDU) 1312 is used between a primary cooling loop 1306 and a second or secondary cooling loop 1308 to enable absorption of heat from a second or secondary cooling loop 1308 to a primary cooling loop 1306. In at least one embodiment, a secondary cooling loop 1308 can access various plumbing into a server tray as required, in an aspect. In at least one embodiment, loops 1306, 1308 are illustrated as line drawings, but a person of ordinary skill would recognize that one or more plumbing features may be used. In at least one embodiment, flexible polyvinyl chloride (PVC) pipes may be used along with associated plumbing to move fluid along in each provided loop 1306; 1308. In at least one embodiment, one or more coolant pumps may be used to maintain pressure differences within coolant loops 1306, 1308 to enable movement of coolant according to temperature sensors in various locations, including in a room, in one or more racks 1310, and/or in server boxes or server trays within one or more racks 1310.

In at least one embodiment, coolant in a primary cooling loop 1306 and in a secondary cooling loop 1308 may be at least water and an additive. In at least one embodiment, an additive may be glycol or propylene glycol. In operation, in at least one embodiment, each of a primary and a secondary cooling loops may have their own coolant. In at least one embodiment, coolant in secondary cooling loops may be proprietary to requirements of components in a server tray or in associated racks 1310. In at least one embodiment, a CDU 1312 is capable of sophisticated control of coolants, independently or concurrently, within provided coolant loops 1306, 1308. In at least one embodiment, a CDU may be adapted to control flow rate of coolant so that coolant is appropriately distributed to absorbed heat generated within associated racks 1310. In at least one embodiment, more flexible tubing 1314 is provided from a secondary cooling loop 1308 to enter each server tray to provide coolant to electrical and/or computing components therein.

The heat transfer fluid generally includes water, water solutions (e.g. propylene glycol-water), brine, antifreeze, a mixture of antifreeze and water, oil, alcohol, mercury or the like or any other suitable heat conductive fluid. The heat transfer fluid may be an electrically conductive cooling liquid and may include water, deionized water, or a coolant such as R-134a, a mixture of water and additives, such as a mixture of water and ethylene glycol or a mixture of water and propylene glycol e.g. a 25% concentration of propylene glycol in deionized water. The heat transfer fluid may also be a dielectric fluid alone (e.g., not having water for purposes of this disclosure) or a water in combination with an additive including at least one dielectric fluid, such as or one or more of de-ionized water, ethylene glycol, and propylene glycol. In at least one embodiment, the heat transfer fluid may be an absorption chiller having a working fluid being a mixed solution containing lithium bromide as the absorbent material and water as the carrier material. The heat transfer fluid may also be a two-phase coolant that has a boiling point that is below the expected operating temperature of the electronic devices. Exemplary two-phase coolants include 2, 3, 3, 3-tetrafluoropropene, 1, 1, 1, 2-tetrafluoroethane and water.

In at least one embodiment, tubing 1318 that forms part of a secondary cooling loop 1308 may be referred to as room manifolds. Separately, in at least one embodiment, further tubing 1316 may extend from row manifold tubing 1318 and may also be part of a secondary cooling loop 1308 but may be referred to as row manifolds. In at least one embodiment, coolant tubing 1314 enters racks as part of a secondary cooling loop 1308 but may be referred to as rack cooling manifold within one or more racks. In at least one embodiment, row manifolds 1316 extend to all racks along a row in a datacenter 1300. In at least one embodiment, plumbing of a secondary cooling loop 1308, including coolant manifolds 1318, 1316, and 1314 may be improved by at least one embodiment herein. In at least one embodiment, a chiller 1320 may be provided in a primary cooling loop within datacenter 1302 to support cooling before a cooling tower. In at least one embodiment, additional cooling loops that may exist in a primary control loop and that provide cooling external to a rack and external to a secondary cooling loop, may be taken together with a primary cooling loop and is distinct from a secondary cooling loop, for this disclosure.

In at least one embodiment, in operation, heat generated within server trays of provided racks 1310 may be transferred to a coolant exiting one or more racks 1310 via flexible tubing of a row manifold 1314 of a second cooling loop 1308. In at least one embodiment, second coolant (in a secondary cooling loop 1308) from a CDU 1312, for cooling provided racks 1310, moves towards one or more racks 1310 via provided tubing. In at least one embodiment, second coolant from a CDU 1312 passes from on one side of a room manifold having tubing 1318, to one side of a rack 1310 via a row manifold 1316, and through one side of a server tray via different tubing 1314. In at least one embodiment, spent or returned second coolant (or exiting second coolant carrying heat from computing components) exits out of another side of a server tray (such as enter left side of a rack and exits right side of a rack for a server tray after looping through a server tray or through components on a server tray). In at least one embodiment, spent second coolant that exits a server tray or a rack 1310 comes out of different side (such as exiting side) of tubing 1314 and moves to a parallel, but also exiting side of a row manifold 1316. In at least one embodiment, from a row manifold 1316, spent second coolant moves in a parallel portion of a room manifold 1318 and is going in an opposite direction than incoming second coolant (which may also be renewed second coolant), and towards a CDU 1312.

In at least one embodiment, spent second coolant exchanges its heat with a primary coolant in a primary cooling loop 1306 via a CDU 1312. In at least one embodiment, spent second coolant may be renewed (such as relatively cooled when compared to a temperature at a spent second coolant stage) and ready to be cycled back to through a second cooling loop 1308 to one or more computing components. In at least one embodiment, various flow and temperature control features in a CDU 1312 enable control of heat exchanged from spent second coolant or flow of second coolant in and out of a CDU 1312. In at least one embodiment, a CDU 1312 may be also able to control a flow of primary coolant in primary cooling loop 1306.

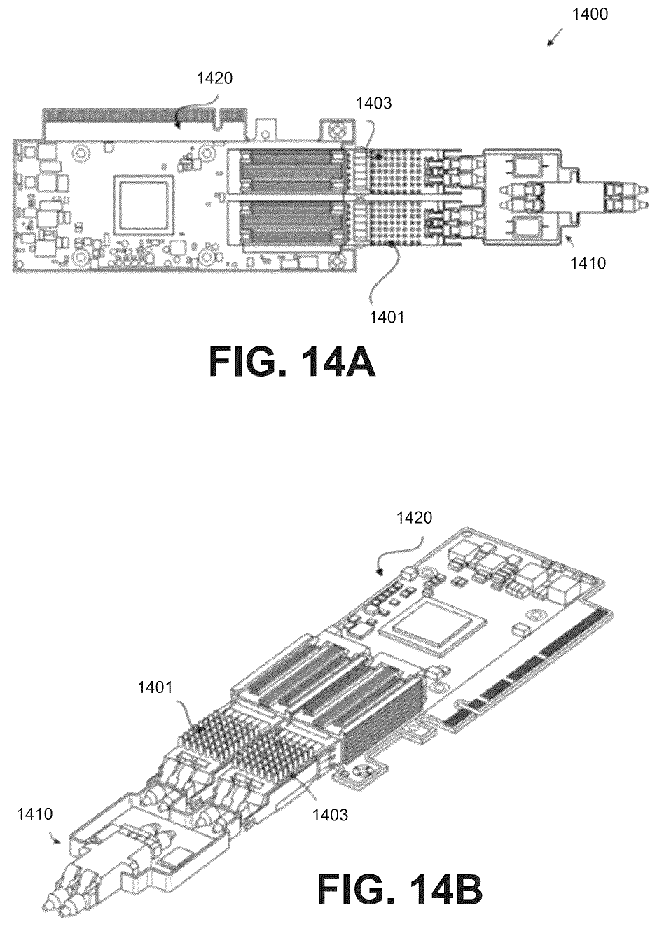

FIGS. 14A and 14B illustrate a top view and a perspective view, respectively, of a transceiver module operatively coupled to a network adapter, in the present example a Network Interface Controller (NIC) 1400, in accordance with an embodiment of the disclosure. As shown in FIGS. 14A and 14B, the transceiver module may include a first optical module 1401, a second optical module 1403, an adapter 1410, and a dual-port NIC 1420 of a server. Both the first optical module 1401 and the second optical module 1403 may be dual-fiber transceivers that are configured for duplex communication that allows the source (e.g., server) to communicate with the target (e.g., leaf switch) in both directions. The adapter 1410 may be a ganged physical component configured to link the first optical module 1401 and the second optical module 1403 for the purpose of transmitting and receiving data to and from the leaf switch.

In some embodiments, the adapter 1410 may be configured to operate in two configurations, such as a first configuration and a second configuration. In one aspect, the first configuration may be a default configuration of operation, where the first optical module 1401 may be operationally active. The second configuration may be a contingent configuration that is implemented when the first optical module 1401 operationally fails. When such a failure is detected, the second optical module 1403, which is otherwise operationally inactive or idle, may be engaged become operationally active and handle all network traffic that was initially handled by the first optical module 1401.

In some embodiments, the transceiver module 1400 may be configured to operate in a leaf-spine architecture. A leaf-spine architecture is a data center network topology that may include two switching layers—a spine layer and a leaf layer. The leaf layer may include access switches (leaf switches) that aggregate traffic from servers and connect directly into the spine or network core. Spine switches interconnect all leaf switches in a full-mesh topology between access switches in the leaf layer and the servers from which the access switches aggregate traffic. As such, in one embodiment, to ensure reliable operation of downlinks, the transceiver module 1400 may be configured to operate between the server and the leaf layer. In particular, as shown in FIGS. 14A and 14B, the adapter 1410 may be operatively coupled to the first optical module 1401 and the second optical module 1403, while the first optical module 1401 and the second optical module 1403 may be operatively coupled to a dual-port NIC 1420 of a server.

In embodiments, NIC 1400 may comprise one or more processing circuits, as detailed above; the processing circuits may comprise FW, that is loaded according to the techniques described above.

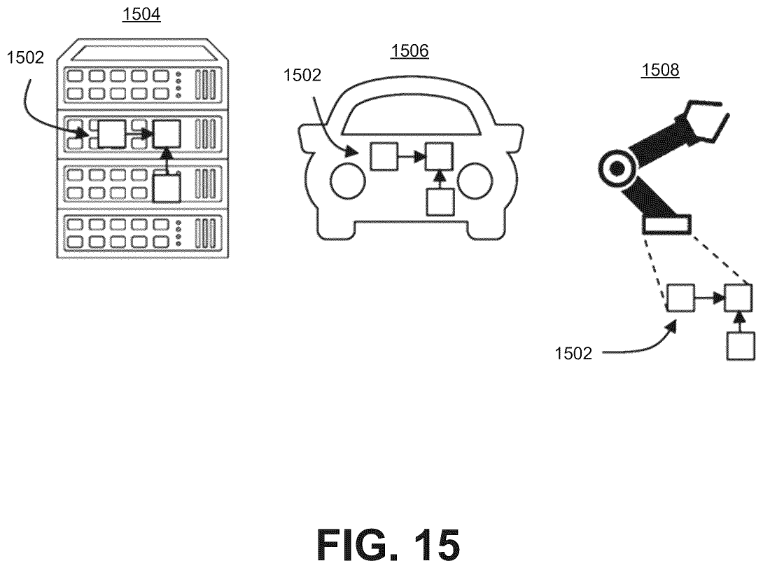

FIG. 15 depicts exemplary scenarios for use of an optical transceiver 1502 in accordance with some embodiments. An optical transceiver 1502 may be utilized in a computing system 1504 (e.g., in a server farm, or within a server computer system), a vehicle 1506 (e.g., a car, truck, train, or airplane), and a robot 1508 (or among robots in a factory), to name just a few examples. The optical transceiver 1502 may be particularly useful for high-speed communication in environments subject to high levels of electromagnetic interference (EMI).

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit the disclosure to a specific form or forms disclosed, but on the contrary, the intention is to cover all modifications, alternative constructions, and equivalents falling within the spirit and scope of the disclosure, as defined in appended claims.

Use of terms “a” and “an” and “the” and similar referents in the context of describing disclosed embodiments (especially in the context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitations of ranges of values herein are merely intended to serve as a shorthand method of referring individually to each separate value falling within the range, unless otherwise indicated herein, and each separate value is incorporated into the specification as if it were individually recited herein. In at least one embodiment, the use of the term “set” (e.g., “a set of items”) or “subset” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but subset and corresponding set may be equal.

Conjunctive language, such as phrases of the form “at least one of A, B, and C,” or “at least one of A, B and C,” unless specifically stated otherwise or otherwise clearly contradicted by context, is otherwise understood with the context as used in general to present that an item, term, etc., may be either A or B or C, or any nonempty subset of the set of A and B and C. For instance, in an illustrative example of a set having three members, conjunctive phrases “at least one of A, B, and C” and “at least one of A, B and C” refer to any of the following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, the term “plurality” indicates a state of being plural (e.g., “a plurality of items” indicates multiple items). In at least one embodiment, the number of items in a plurality is at least two, but can be more when so indicated either explicitly or by context. Further, unless stated otherwise or otherwise clear from context, the phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in the form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause a computer system to perform operations described herein. In at least one embodiment, a set of non-transitory computer-readable storage media comprises multiple non-transitory computer-readable storage media and one or more of individual non-transitory storage media of multiple non-transitory computer-readable storage media lack all of the code while multiple non-transitory computer-readable storage media collectively store all of the code. In at least one embodiment, executable instructions are executed such that different instructions are executed by different processors.

Accordingly, in at least one embodiment, computer systems are configured to implement one or more services that singly or collectively perform operations of processes described herein and such computer systems are configured with applicable hardware and/or software that enable the performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

In description and claims, terms “coupled” and “connected,” along with their derivatives, may be used. It should be understood that these terms may not be intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, the term “processor” may refer to any device or portion of a device that processes electronic data from registers and/or memory and transform that electronic data into other electronic data that may be stored in registers and/or memory. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously, or intermittently. In at least one embodiment, terms “system” and “method” are used herein interchangeably insofar as the system may embody one or more methods and methods may be considered a system.

In the present document, references may be made to obtaining, acquiring, receiving, or inputting analog or digital data into a subsystem, computer system, or computer-implemented machine. In at least one embodiment, the process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface or inter-process communication mechanism.

Although descriptions herein set forth example embodiments of described techniques, other architectures may be used to implement described functionality, and are intended to be within the scope of this disclosure. Furthermore, although specific distributions of responsibilities may be defined above for purposes of description, various functions and responsibilities might be distributed and divided in different ways, depending on circumstances.

Furthermore, although the subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A system, comprising:
a sliding member configured to move a cold plate between a first configuration and a second configuration, wherein in the first configuration the cold plate is positioned away from a surface of an interconnect module, and wherein in the second configuration the cold plate is positioned in thermal communication with the interconnect module.

2. The system of claim 1, further comprising:
the cold plate, wherein the cold plate is configured to cool the interconnect module; and
a thermal interface pad on a cooling surface of the cold plate, wherein the thermal interface pad does not contact the interconnect module when the cold plate is supported in the first configuration, and wherein the thermal interface pad contacts the interconnect module when the cold plate is in the second configuration.

3. The system of claim 2, wherein the thermal interface pad comprises graphene.

4. The system of claim 2, wherein the system is configured to receive a plurality of insertions and removals of the interconnect module without damage to the thermal interface pad and without mechanical failure of the sliding member.

5. The system of claim 1, wherein a thermal interface between the interconnect module and the cold plate has a thermal resistance less than approximately 0.2 Kelvin per Watt (K/W).

6. The system of claim 1, wherein the sliding member is configured to translationally slide between a first translational position corresponding to the first configuration and a second translational position corresponding to the second configuration.

7. The system of claim 6, wherein during insertion of the interconnect module into a receptacle, the interconnect module is to push the sliding member from the first translational position to the second translational position.

8. The system of claim 6, wherein in the first translational position the sliding member positions the cold plate at a first vertical position away from the interconnect module, wherein in the second translational position the sliding member positions the cold plate at a second vertical position, and wherein in the second vertical position the cold plate is in thermal communication with the interconnect module.

9. The system of claim 8, wherein the sliding member forms a ramp feature configured to interact with a protrusion of the cold plate, and wherein the protrusion is to slide along the ramp feature to vertically move the cold plate between the first vertical position and the second vertical position as the sliding member translationally slides between the first translational position and the second translational position respectively.

10. The system of claim 9, wherein the sliding member comprises two substantially parallel members coupled by at least one bridge member, and wherein each of the two substantially parallel members form at least one ramp feature.

11. The system of claim 6, further comprising:
one or more first springs configured to exert a first spring force on the sliding member, wherein the first spring force is in a first direction corresponding to movement of the sliding member from the second translational position to the first translational position.

12. The system of claim 11, further comprising:
one or more second springs configured to exert a second spring force on the cold plate, wherein the second spring force is in a second direction toward the interconnect module coupled within the receptacle.

13. A system, comprising:
a sliding member configured to adjust a height of a cold plate between a first height and a second height during insertion of an interconnect module into a receptacle, wherein adjustment to the height of the cold plate minimizes a shear force on a thermal interface pad of the cold plate during insertion of the interconnect module into the receptacle.

14. The system of claim 13, wherein the thermal interface pad does not contact the interconnect module when the cold plate is at the first height, and wherein the thermal interface pad contacts the interconnect module when the cold plate is at the second height.

15. The system of claim 13, wherein a thermal interface between the interconnect module and the cold plate formed at least partially by the thermal interface pad has a thermal resistance less than approximately 0.2 Kelvin per Watt (K/W).

16. The system of claim 13, wherein when the cold plate is at the first height, the cold plate is positioned vertically away from the interconnect module, and wherein when the cold plate is at the second height, the cold plate is in thermal communication with the interconnect module.

17. The system of claim 13, wherein the sliding member is configured to translationally slide between a first translational position and a second translational position, wherein when the sliding member is in the first translational position the cold plate is adjusted to the first height, and wherein when the sliding member is in the second translational position the cold plate is adjusted to the second height.

18. The system of claim 17, wherein during insertion of the interconnect module into the receptacle, the interconnect module is to push the sliding member from the first translational position to the second translational position.

19. The system of claim 17, wherein the sliding member forms a ramp feature configured to interact with a protrusion of the cold plate, and wherein the protrusion is to slide along the ramp feature to vertically move the cold plate between the first height and the second height as the sliding member translationally slides between the first translational position and the second translational position respectively.

20. The system of claim 17, further comprising:
one or more first springs configured to exert a first spring force on the sliding member, wherein the first spring force is in a first direction corresponding to movement of the sliding member from the second translational position to the first translational position; and
one or more second springs configured to exert a second spring force on the cold plate, wherein the second spring force is in a second direction toward the interconnect module coupled within the receptacle.

21. A computing server, comprising:
a receptacle configured to receive an interconnect module;
a cold plate; and
a sliding member configured to move the cold plate between a first configuration and a second configuration, wherein the first configuration the cold plate is positioned away from a surface of the interconnect module inserted into the receptacle, and wherein in the second configuration the cold plate is positioned in thermal communication with the interconnect module.

22. The computing server of claim 21, further comprising:
a thermal interface pad on a cooling surface of the cold plate, wherein the thermal interface pad does not contact the interconnect module when the cold plate is supported in the first configuration, and wherein the thermal interface pad contacts the interconnect module when the cold plate is in the second configuration.

23. The computing server of claim 21, wherein the sliding member is configured to translationally slide between a first translational position corresponding to the first configuration and a second translational position corresponding to the second configuration, and wherein during insertion of the interconnect module into the receptacle, the interconnect module is to push the sliding member from the first translational position to the second translational position.

24. The computing server of claim 23, wherein in the first translational position the sliding member positions the cold plate at a first vertical position away from the interconnect module, wherein in the second translational position the sliding member positions the cold plate at a second vertical position, and wherein in the second vertical position the cold plate is in thermal communication with the interconnect module.

25. The computing server of claim 24, wherein the sliding member forms a ramp feature configured to interact with a protrusion of the cold plate, and wherein the protrusion is to slide along the ramp feature to vertically move the cold plate between the first vertical position and the second vertical position as the sliding member translationally slides between the first translational position and the second translational position respectively.

26. The computing server of claim 23, further comprising:
one or more first springs configured to exert a first spring force on the sliding member, wherein the first spring force is in a first direction corresponding to movement of the sliding member from the second translational position to the first translational position; and
one or more second springs configured to exert a second spring force on the cold plate, wherein the second spring force is in a second direction toward the interconnect module coupled within the receptacle.

27. A datacenter, comprising:
one or more computing servers, wherein at least one of the one or more computing servers comprises:
a receptacle configured to receive an interconnect module;
a cold plate; and
a sliding member configured to move the cold plate between a first configuration and a second configuration, wherein the first configuration the cold plate is positioned away from a surface of the interconnect module inserted into the receptacle, and wherein in the second configuration the cold plate is positioned in thermal communication with the interconnect module.

28. The datacenter of claim 27, wherein the at least one of the one or more computing servers further comprises:
a thermal interface pad on a cooling surface of the cold plate, wherein the thermal interface pad does not contact the interconnect module when the cold plate is supported in the first configuration, and wherein the thermal interface pad contacts the interconnect module when the cold plate is in the second configuration.

29. The datacenter of claim 27, wherein the sliding member is configured to translationally slide between a first translational position corresponding to the first configuration and a second translational position corresponding to the second configuration, and wherein during insertion of the interconnect module into the receptacle, the interconnect module is to push the sliding member from the first translational position to the second translational position.
